(19) United States
(12) Patent Application Publication
(10) Pub. No.: US 2009/0269579 A1
(43) Pub. Date: Oct. 29, 2009

(54) MULTILAYER STRUCTURED PARTICLE

(75) Inventor: Masashi Minaki, Kyoto-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SANYO CHEMICAL INDUSTRIES, LTD., Kyoto-shi, Kyoto (JP)

(21) Appl. No.: 11/917,939

(22) PCT Filed: Aug. 28, 2007
(86) PCT No.: PCT/JP2007/000924

§ 371 Date: Dec. 18, 2007

(30) Foreign Application Priority Data
Feb. 19, 2007 (JP) 2007-038043
Mar. 14, 2007 (JP) 2007-064418

(51) Int. Cl. B32B 5/16; C23C 16/48; B01J 13/00; B32B 1/00; F21V 9/00; C09D 1/00

(52) U.S. Cl. 428/338; 428/221; 427/596; 427/214; 428/403; 428/407; 252/582; 524/430; 524/432; 524/433; 524/543; 524/589; 524/599

(57) ABSTRACT

An object of the present invention is to provide a multilayer structured particle which can transmit or reflect light having a specific wavelength selectively within a wide range and a simple and easy method for producing the same.

The multilayer structured particle of the present invention is characterized in that a central layer (L0) is provided as a core and two or more layers (Ln) are disposed concentrically with respect to the center of the core, wherein every pair of adjacent layers has a refractive index difference of from 0.01 to 1.5 and at least one layer of the central layer (L0) and the layers (Ln) is a metal oxide layer (M).

The method of the present invention for producing a multilayer structured particle is characterized in that the method includes at least two steps, a repetition of at least two steps, or a repetition of at least one step selected from the group consisting of production step (10) of using pulse laser irradiation, production step (20) of using a gaseous metal compound, production step (30) of using a sol-gel method or a double micell layer, and utilization of a sol-gel method (40); or production step (50) of using a double micell layer or production step (60) of using opposite charges.

### TECHNICAL FIELD

The present invention relates to a multilayer structured particle.

### BACKGROUND ART

Heretofore, as particles with a multilayer structure, for example, a multilayer polymer fine particle comprising two types of polymer layers satisfying a relation that the difference in interfacial tension with water is greater than 0.1 (mN/m) disposed concentrically one on another in four or more layers (see, for example, Patent Document 1), a multilayer structured polymer particle comprising a crosslinked methyl methacrylate layer, a crosslinked elastic alkyl acrylate layer and a hard thermoplastic methyl methacrylate layer (see, for example, Patent Document 2), and the like are disclosed.

Patent Document 1: JP 2004-35785 A

Patent Document 2: JP 2004-352837 A

### DISCLOSURE OF THE INVENTION

### Problems to be Solved by the Invention

However, conventional particles have a problem that they can not transmit or reflect light having a specific wavelength selectively within a wide range.

One of the problems to be solved by the present invention is to provide a multilayer structured particle which can transmit or reflect light having a specific wavelength selectively within a wide range. Another problem is to provide a method for producing such a multilayer structured particle simply and easily.

### Means for Solving the Problems

The gist of the features of the multilayer structured particle of the present invention is that a central layer (L0) is provided as a core and two or more layers (Ln) are disposed concentrically with respect to the center of the core, wherein every pair of adjacent layers has a refractive index difference (at 25° C.) of from 0.01 to 1.5 and at least one layer of the central layer (L0) and the layers (Ln) is a metal oxide layer (M).

The gist of the features of the method of the present invention for producing a multilayer structured particle is that the method includes at least two steps, a repetition of at least two steps, or a repetition of at least one step selected from the group consisting of production steps (10), (20), (30), and (40):

production step (10) of obtaining a multilayer structured particle by obtaining a multilayer particle dispersion liquid by placing a lump of a resin or a metal oxide in a dispersion liquid (D0) containing a central layer (L0) dispersed therein or a dispersion liquid (Dn) containing a multilayer particle dispersed therein and applying a pulse laser to the lump to generate fine particles and thereby form a resin layer (R) or a metal oxide layer (M) on the surface of the central layer (L0) or the multilayer particle;

production step (20) of obtaining a multilayer structured particle by reacting either a central layer (L0) having a reactive group (a) or a multilayer particle having a reactive group (a) in its surface and a gaseous metal compound together by heating to form a metal compound layer on the surface of the central layer (L0) or the multilayer particle and thereby obtain a metal compound layer particle, then removing the unreacted gaseous metal compound, and reacting the metal compound layer particle and water vapor together to change the metal compound layer into a metal oxide layer (M) to obtain a multilayer particle;

production step (30) of obtaining a multilayer structured particle by including at least one step selected from

step (31) of obtaining a multilayer particle dispersion liquid by adding a metal alkoxide to a dispersion liquid (D0) containing a central layer (L0) of a resin having active hydrogen dispersed in an alcohol having 1 to 4 carbon atom(s) or an aprotic solvent (E31) or a dispersion liquid (Dn) containing a multilayer particle having a surface composed of a resin layer having active hydrogen dispersed in an alcohol having 1 to 4 carbon atom(s) or an aprotic solvent (E31) to thereby form a metal oxide layer on the surface of the central layer (L0) or the multilayer particle by a sol-gel method;

step (32) comprising adding, to a dispersion liquid containing a cationic or anionic reactive surfactant (S1) which is copolymerizable with a resin precursor (m) and a multilayer particle having a metal oxide layer on its surface or a central layer (L0) composed of a metal oxide, a reactive surfactant (S2) which is copolymerizable with the resin precursor (m) and has the opposite ionicity to that of the reactive surfactant (S1), and the resin precursor (m), then copolymerizing the reactive surfactant (S1), the reactive surfactant (S2), and the resin precursor (m) to form a resin layer on the surface of the multilayer particle or the central layer (L0) to thereby obtain a multilayer particle dispersion liquid, and then isolating a multilayer particle;

step (33) comprising adding, to a dispersion liquid containing a cationic or anionic reactive surfactant (S1) which is copolymerizable with a resin precursor (m) and a multilayer particle having a resin layer on its surface or a central layer (L0) composed of a resin, a reactive surfactant (S2) which is copolymerizable with the resin precursor (m) and has the opposite ionicity to that of the reactive surfactant (S1), and the resin precursor (m), then copolymerizing the reactive surfactant (S1), the reactive surfactant (S2), and the resin precursor (m) to form a resin layer on the surface of the multilayer particle or the central layer (L0) to thereby obtain a multilayer particle dispersion liquid, and then isolating a multilayer particle; and

step (34) of obtaining a multilayer particle dispersion liquid by adding a metal alkoxide to a dispersion liquid (D0) containing a central layer (L0) of a metal oxide having active hydrogen dispersed in an alcohol having 1 to 4 carbon atom(s) or an aprotic solvent (E31) or a dispersion liquid (Dn) containing a multilayer particle having a surface composed of a metal oxide having active hydrogen dispersed in an alcohol having 1 to 4 carbon atom(s) or an aprotic solvent (E31) to thereby form a metal oxide layer on the surface of the central layer (L0) or the multilayer particle by a sol-gel method;

production step (40) of obtaining a multilayer particle dispersion liquid by adding a metal alkoxide to a dispersion liquid (D0) containing a central layer (L0) of a resin or a metal oxide having active hydrogen dispersed in an alcohol having 1 to 4 carbon atom(s) or an aprotic solvent (E31) or a dispersion liquid (Dn) containing a multilayer particle having a surface composed of a resin layer or a metal oxide layer having active hydrogen dispersed in an alcohol having 1 to 4 carbon atom(s) or an aprotic solvent (E31) to thereby form a metal oxide layer on the surface of the central layer (L0) or the multilayer particle by a sol-gel method.

The gist of the features of the method of the present invention for producing a multilayer structured particle is that the method includes:

production step (50) comprising adding, to a dispersion liquid containing a cationic or anionic reactive surfactant (S1) which is copolymerizable with a resin precursor (m) and a central layer (L0) composed of a resin or a multilayer particle having a surface composed of a resin layer, a reactive surfactant (S2) which is copolymerizable with the resin precursor (m) and has the opposite ionicity to that of the reactive surfactant (S1), and the resin precursor (m), then copolymerizing the reactive surfactant (S1), the reactive surfactant (S2), and the resin precursor (m) to form a resin layer on the surface of the central layer (L0) or the multilayer particle to thereby obtain a multilayer particle dispersion liquid, subsequently isolating a multilayer particle, and repeating the foregoing operations to obtain a multilayer structured particle; or

production step (60) of obtaining a multilayer structured particle by adding, to a dispersion liquid (D0) containing a central layer (L0) dispersed therein which is composed of a resin and whose surface has a charge (q) or a dispersion liquid (Dn) containing a multilayer particle dispersed therein whose surface is composed of a resin layer and has a charge (q), a resin particle (P0) having a particle diameter as small as 1/10 or less of the particle diameter of the central layer (L0) or the multilayer particle and having a charge (r) with a sign opposite to that of the charge (q) to form a resin layer composed of the resin particle (P0) on the surface of the central layer (L0) or the multilayer particle to thereby obtain a multilayer particle dispersion liquid, and repeating the foregoing operation.

### EFFECT OF THE INVENTION

The multilayer structured particle of the present invention can selectively transmit or reflect light having a specific wavelength within a wide range (i.e., it possesses excellent functions of extracting light having a specific wavelength through interference of light or scattering light efficiently). Therefore, the multilayer structured particle of the present invention can be used as, for example, a colorant which is resistant to fading even in long-term use and which has a high color purity.

By use of the production method of the present invention, it is possible to produce this multilayer structured particle simply and easily.

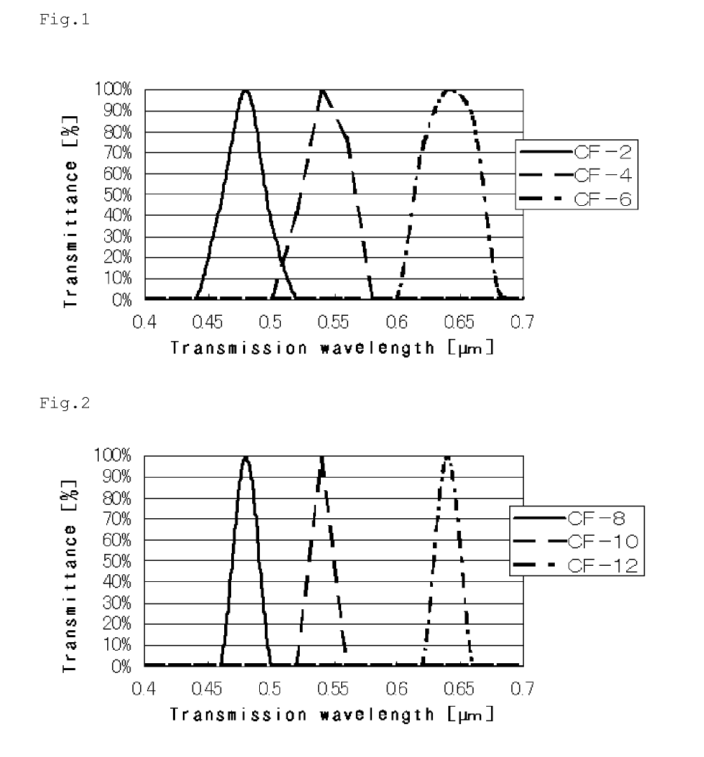

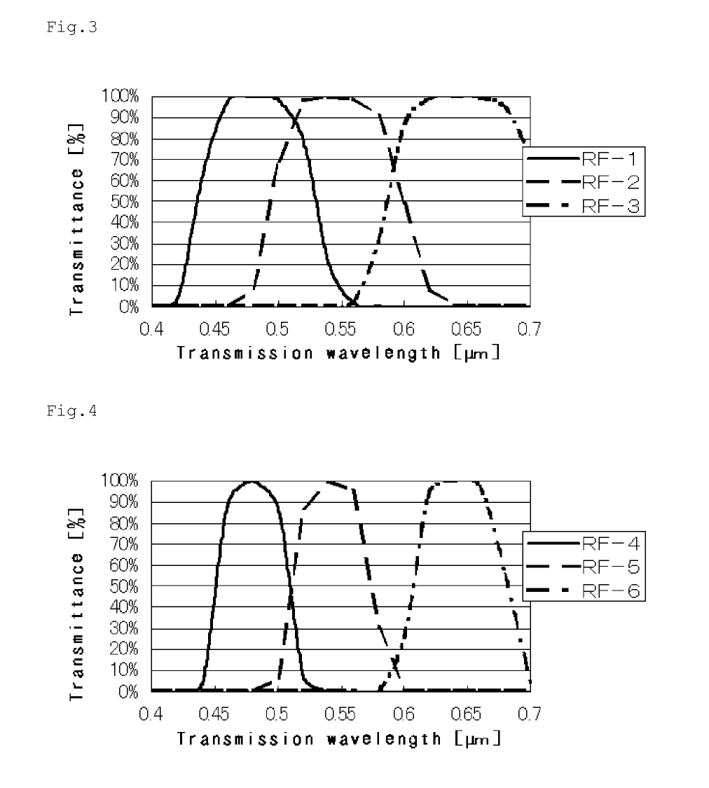

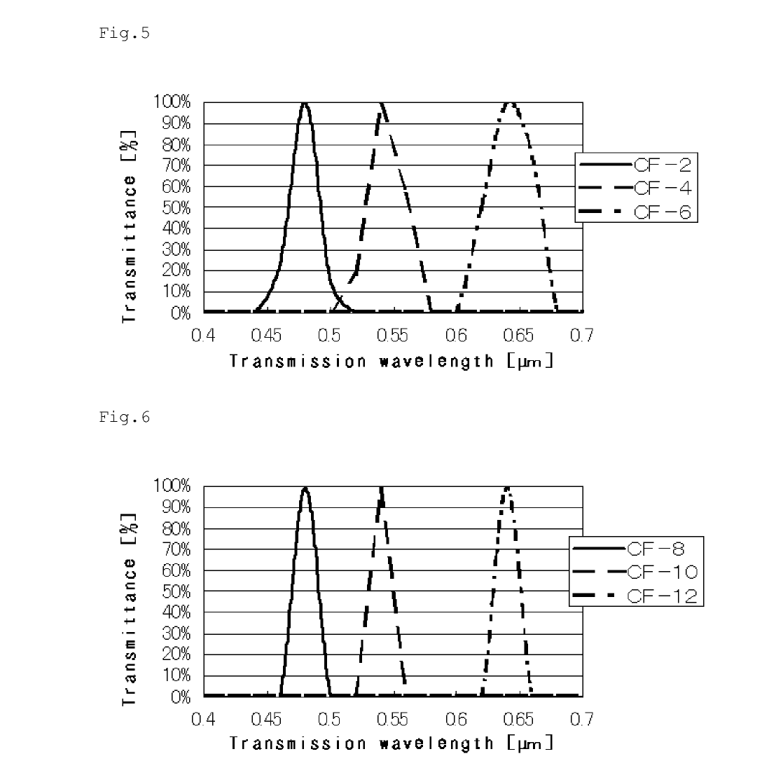

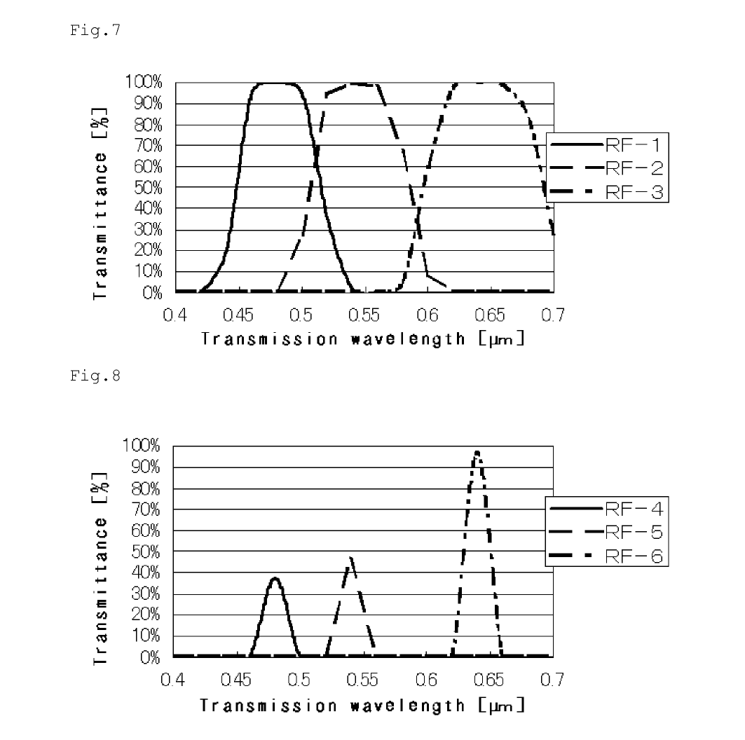

### BRIEF DESCRIPTION OF THE DRAWINGS

[FIG. 1] A graph showing the relationship between the transmission wavelength and the transmittance for the treated substrates prepared by using the multilayer structured spherical particles obtained in Examples 2 (CF-2), 4 (CF-4) and 6 (CF-6).

[FIG. 2] A graph showing the relationship between the transmission wavelength and the transmittance for the treated substrates prepared by using the multilayer structured spherical particles obtained in Examples 8 (CF-8), 10 (CF-10) and 12 (CF-12).

[FIG. 3] A graph showing the relationship between the transmission wavelength and the transmittance for the treated substrates prepared by using comparative particles 1 (RF-1), 2 (RF-2) and 3 (RF-3).

[FIG. 4] A graph showing the relationship between the transmission wavelength and the transmittance for the treated substrates prepared by using comparative particles 4 (RF-4), (RF-5) and 6 (RF-6).

[FIG. 5] A graph showing the relationship between the transmission wavelength and the transmittance for the treated substrates after 1000-hour irradiation with ultraviolet rays to the treated substrates prepared by using the multilayer structured spherical particles obtained in Examples 2 (CF-2), 4 (CF-4) and 6 (CF-6).

[FIG. 6] A graph showing the relationship between the transmission wavelength and the transmittance for the treated substrates after 1000-hour irradiation with ultraviolet rays to the treated substrates prepared by using the multilayer structured spherical particles obtained in Examples 8 (CF-8), (CF-10) and 12 (CF-12).

[FIG. 7] A graph showing the relationship between the transmission wavelength and the transmittance for the treated substrates after 1000-hour irradiation with ultraviolet rays to the treated substrates prepared by using comparative particles 1 (RF-1), 2 (RF-2) and 3 (RF-3).

[FIG. 8] A graph showing the relationship between the transmission wavelength and the transmittance for the treated substrates after 1000-hour irradiation with ultraviolet rays to the treated substrates prepared by using comparative particles 4 (RF-4), 5 (RF-5) and 6 (RF-6).

### BEST MODE FOR CARRYING OUT THE INVENTION

### Multilayer Structured Particle

The central layer (L0) is not particularly restricted about its external shape as long as it forms a core, but it is preferably in the form of a spherical particle with a mean circularity of from 0.96 to 1 or a non-spherical particle with a mean circularity of not less than 0.7 but less than 0.96, more preferably a spherical particle with a mean circularity of from 0.97 to 1 or a non-spherical particle with a mean circularity of from 0.80 to 0.95, and particularly preferably a spherical particle with a mean circularity of from 0.98 to 1 or a non-spherical particle with a mean circularity of from 0.85 to 0.93.

The mean circularity is an arithmetic average obtained by calculating a circumference distance (r1) of a true circle converted from the “largest sectional area” among sectional areas of a particle, then producing a value calculated by dividing the circumference distance (r1) by an “actually measured circumference distance (r2)” of the largest sectional area for at least 1000 particles, and finally averaging these values.

The “largest sectional area” is determined by forcing a dispersion liquid of a sample to flow in a narrow gap, applying light perpendicularly to the flow direction, and image processing the shadow of the flow.

The “actually measured circumference distance (r2)” is obtained by finely dividing the image processing data obtained in the determination of the “largest sectional area” and counting division points on the circumference.

All of the layers (Ln) are disposed concentrically one on another with respect to the center of the core. The layers (Ln) include two or more layers and preferably, from the viewpoint of selective transmission or reflection of light having a specific wavelength in a wide range, three or more layers, more preferably four or more layers, even more preferably five or more layers, and most preferably six or more layers. On the other hand, from the viewpoint of production or the like, the number of the layers is preferably not more than 30 layers.

The “n” in the “layer (Ln)” corresponds to each layer and is an integer of 1 or more. The “n” of the layer adjacent to the central layer (L0) is 1 and the “n” increases toward the outside. That is, a layer (L1) is disposed on the surface of the central layer (L0) and a layer (L2) is disposed on the surface of the layer (L1). Likewise, layers (L3), (L4) and the like are disposed outward one on another.

The refractive index difference (at 25° C.) of any adjacent layers among all of the central layer (L0) and the layers (Ln) is from 0.01 to 1.5, preferably from 0.05 to 1.5, more preferably from 0.1 to 1.5, particularly preferably from 0.2 to 1.5, even more preferably from 0.5 to 1.5, and most preferably from 1 to 1.5. If it is within such ranges, selective transmission or reflection of light having a specific wavelength in a wide range is improved. If it is less than the lower limit, light is difficult to be reflected or interfered sufficiently; on the other hand, if it is greater than the upper limit, raw materials for the production of multilayer structured particles become difficult to get.

Regarding the refractive index (at 25° C.), a layer (Ln) having a thickness of v2 is formed on a base film (thickness: v1) having a refractive index of a1 to produce a laminated film and a refractive index (W) of the laminated film is then measured, followed by calculation of a refractive index (a2) of the layer (Ln) according to the following formula:

a2={W−(a1v1/(v1+v2))}×{(v1+v2)/v2}.

The thickness (μm) of each layer (Ln) is preferably from 0.01 to 3. From the viewpoint of selective transmission of light having a specific wavelength in a wide range or the like, it is more preferably from 0.01 to 0.2, and particularly preferably from 0.02 to 0.1. On the other hand, from the viewpoint of selective reflection (diffusion) of light having a specific wavelength in a wide range or the like, it is more preferably from 0.1 to 3, and particularly preferably from 0.5 to 2.

The thickness (μm) of the central layer (L0) is preferably from 0.05 to 3, and more preferably from 0.1 to 2.5.

The thickness of the central layer (L0) means the mean distance from the center of the core forming the central layer (L0) to the surface of the central layer.

The thicknesses of the central layer (L0) and the layers (Ln) can be measured by fixing the multilayer structured particle with a resin, cutting it with a diamond cutter or the like, and analyzing the cross section of the multilayer structured particle using a transmission electron microscope (TEM).

The standard deviation of the thickness of at least one layer of the layers (Ln) is preferably, from the viewpoint of uniform interference of light, not greater than 30%, and more preferably not greater than 25%.

The volume mean particle diameter (μm) of the multilayer structured particle of the present invention is preferably, from the viewpoint of color purity or the scattering property of light, from 0.1 to 20, more preferably from 0.5 to 15, and particularly preferably from 1 to 10.

The volume mean particle diameter can be measured by dispersing a sample to be measured in water, followed by measurement using a light-scattering particle size distribution analyzer {e.g., LA-950 produced by HORIBA, Ltd.}.

The volume (% by volume) of the central layer (L0) is preferably, from the viewpoint of light transmitting property, from 5 to 98, and more preferably from 10 to 90 based on the volume of the multilayer structured particle.

The volume of the central layer (L0) can be measured by fixing the multilayer structured particle with a resin, cutting it with a diamond cutter or the like, and analyzing the cross section of the multilayer structured particle using a transmission electron microscope (TEM).

It is only required that at least one layer of the central layer (L0) and the layers (Ln) be a metal oxide layer (M). That is, all the layers may be metal oxide layers (M), or a metal oxide layer (M) and another layer {for example, a resin layer (R)} may be present together.

When another layer {for example, a resin layer (R)} and a metal oxide layer (M) are present together, the particle preferably has a structure in which another layer {for example, a resin layer (R)} and a metal oxide layer (M) are disposed one on another.

The central layer (L0) may be either a metal oxide layer (M) or another layer {for example, a resin layer (R)}, but a metal oxide layer (M) is preferred.

Examples of the metal oxide which can form the metal oxide layer (M) include silica, alumina, magnesium oxide, zinc oxide, titanium oxide, zirconium oxide, antimony oxide, and natural substances containing these metal oxides. Examples of such natural substances include talc, kaolin clay, montmorillonite, mica, bentonite, agalmatolite clay, chrysotile, and the like.

Among these substances, at least one substance selected from the group consisting of silica, alumina, magnesium oxide, zinc oxide, and titanium oxide is preferred, and at least one substance selected from the group consisting of silica, alumina, and titanium oxide is more preferred, in light of ease of production and refractive index.

The another layer may include resin layers (R), metal nitride layers, and the like. Among such layers, resin layers (R) are preferred from the viewpoint of ease of production.

Resins which can form a resin layer (R) include colorless, film-forming resins. Preferred from the viewpoint of transparency and refractive index, is at least one resin selected from the group consisting of polyurethane, polyester, vinyl resin, fluororesin, and polyamide. At least one resin selected from the group consisting of vinyl resin, fluororesin, and polyamide is more preferred.

It is desirable that a resin layer (R) contains a crosslinked resin.

Examples of such crosslinked resin include crosslinked vinyl resins resulting from copolymerization of monomers having two or more vinyl groups in each molecule, crosslinked urethane resins resulting from copolymerization of monomers or prepolymers having three or more isocyanato groups in each molecule, crosslinked epoxy resins resulting from copolymerization of monomers or prepolymers having three or more glycidyl groups, amino groups, or carboxy groups in each molecule, crosslinked polyamides resulting from copolymerization of monomers or prepolymers having three or more amino groups, carboxy groups, or carboxylic anhydride groups {1,3-oxo-2-oxapropylene groups} in each molecule, and the like.

When a crosslinked resin is included, the content (% by weight) of the crosslinked resin is preferably from 30 to 100, and more preferably from 50 to 100, based on the weight of the resin layer (R).

The multilayer structured particle of the present invention is not particularly restricted about its external shape, but it is preferably in the form of a spherical particle with a mean circularity of from 0.96 to 1 or a non-spherical particle with a mean circularity of not less than 0.7 but less than 0.96, more preferably a spherical particle with a mean circularity of from 0.97 to 1 or a non-spherical particle with a mean circularity of from 0.80 to 0.95, and particularly preferably a spherical particle with a mean circularity of from to 1 or a non-spherical particle with a mean circularity of from 0.85 to 0.93. The external shape of the multilayer structured particle of the present invention greatly depends on that of the central layer (L0).

When each layer in the multilayer structure has a thickness of from 0.01 to 0.2 μm, the light reflected on a certain layer and the light reflected on a layer located inside or outside the certain layer interfere, and therefore light with a wavelength corresponding to the thickness and refractive index of the layer appears colored (a structural color is shown) The structural color appears in various colors depending on the viewing angle. However, when the multilayer structured particle is a spherical particle, the viewing angle is fixed and therefore a single color (monochromatic light) is observed. When the refractive index difference of adjacent layers is increased or when the number of layers is increased, the reflection efficiency becomes greater (the amount of the reflected light based on that of the incident light increases) and as a result a strong structural color is shown.

On the other hand, in a multilayer structure in which each layer has a thickness of from 0.1 to 3 μm, interference of light does not occur and reflection of light occurs on each layer. The more the number of layers is, the more efficiently the scattering of light occurs. Non-spherical particles cause the scattering of light more efficiently than spherical particles.

It is preferred that at least one layer selected from the central layer (L0) and the layers (Ln) contains a colorant (D). As such a colorant (D), at least one substance selected from the group consisting of dyes, pigments, and fluorescent materials is preferred in light of the purity of light emitted and the color reproduction.

Examples of such dyes include acid alizarin violet N, acid black, acid blue, acid chrome violet K, acid Fuchsin, acid green, acid orange, acid red, acid violet 6B, Direct yellow, Direct Orange, Direct Violet, Direct Blue, Direct Green, Mordant Yellow, Mordant Orange, Mordant Violet, Mordant Green, Food Yellow 3, and derivatives of these dyes. Dyes other than those listed above (e.g., azo based, xanthene based or phthalocyanine based acid dyes) can be used as well. C. I. Solvent Blue 44, 38, C. I. Solvent Orange 45, Rhodamine B, Rhodamine 110, 2,7-Naphthalenedisulfonic acid, and derivatives of these dyes can be used as well.

Examples of such pigments include red colorants (e.g., a mixture of C. I. Pigment Red 254 and C. I. Pigment Red 177), green colorants (e.g., a mixture of C. I. Pigment Green 36 and C. I. Pigment Yellow 150 or C. I. Pigment Yellow 138), blue colorants (e.g., C. I. Pigment Blue 15, C. I. Pigment Blue 22, C. I. Pigment Blue 60, and C. I. Pigment Blue 64), and the like.

The fluorescent material is selected from inorganic fluorescent materials {e.g., oxides, sulfides, silicates and vanadates of rare earth elements (e.g., zinc, cadmium, magnesium, silicon, and yttrium)}, organic fluorescent materials {e.g., fluorescein, eosin, and oils (mineral oils)} and the like. The activator is selected from silver, copper, manganese, chromium, europium, zinc, aluminum, lead, phosphorus, arsenic, gold and the like. The solvent is selected from sodium chloride, potassium chloride, magnesium carbonate, barium chloride and the like.

If a colorant (D) is contained, the content (% by weight) of the colorant (D) is preferably from 0.1 to 10, and more preferably from 0.5 to 5 based on the weight of the multilayer structured particle.

### <Method of Producing Multilayer Structured Particles>

When the central layer (L0) is a spherical resin layer, the central layer (L0) is obtained by a general method, such as emulsion polymerization, suspension polymerization, miniemulsion polymerization, or dispersion polymerization. In the case where the central layer (L0) is a spherical metal oxide layer (M), it is obtained by a sol-gel method, or the like.

In the case where the central layer (L0) is a non-spherical resin layer, the central layer (L0) is produced by, for example, the following known methods (1) to (5).

(1) A method in which in emulsion polymerization, suspension polymerization or the like, a thickener {a water-soluble polymer (e.g., polyvinyl alcohol, carboxymethylcellulose, or polyvinyl pyrrolidone)} is added to a continuous phase, and a polymerization reaction is carried out under stirring.

(2) A method in which a product is produced by dispersing a thermoplastic resin in a solvent, heating to the glass transition temperature of the thermoplastic resin or more, and agitating and cooling under a high share.

(3) A method in which a product is produced by swelling resin particles with a solvent and removing the solvent under a high share.

(4) A method in which a product is produced by copolymerizing monomers together with a crosslinking agent in emulsion polymerization, suspension polymerization method, or the like, and utilizing the volume shrinkage through a crosslinking reaction.

(5) A method in which a product is produced by pulverizing resin particles or metal oxide particles.

Among these, the method (1), (2) or (3) is preferred from the viewpoint of light scattering property and surface smoothness.

When the central layer (L0) is a non-spherical metal layer, the central layer (L0) is produced, for example, by a method including application of the above-mentioned method (1) to a pulverization method and a sol-gel method.

The multilayer structured particle of the present invention can be produced by providing a central layer (L0) as a core, and disposing two or more layers (Ln) concentrically with respect to the center of the core.

Examples of the method for producing a multilayer structured particle by providing a central layer (L0) as a core and disposing two or more layers (Ln) concentrically with respect to the center of the core include production method (1) including at least two steps, a repetition of at least two steps or a repetition of one step selected from the group consisting of production steps (10), (20), (30) and (40); production method (2) including production step (50) or production step (60); and another production method (3).

### 1. Production Method (1)

### 1-1. Production Step (10)

Production step (10) includes obtaining a two-layer particle dispersion liquid by placing a lump of a resin or a metal oxide for forming a layer (L1) in a dispersion liquid (D0) containing a central layer (L0) dispersed therein and applying a pulse laser toward the lump to generate fine particles and thereby form a resin layer (R1) or a metal oxide layer (M1) on the surface of the central layer (L0) {preferably, two-layer particles are then isolated}.

A multilayer structured particle can be obtained by subsequently combining production steps (20), (30) and/or (40). On the other hand, three-layer particles can be obtained by subjecting a two-layer structured particle dispersion liquid {preferably, a dispersion liquid in which isolated two-layer particles are dispersed} (D1) to operations in the same manner as described above. Repetition of such operations can afford a multilayer structured particle. Further, a multilayer structured particle can be obtained by preparing a dispersion liquid (Dn) in which the multilayer particles having been obtained through the production steps (20), (30) and/or (40) are dispersed and treating it in the same manner as described above.

Regarding the dispersion of the central layer (L0) or the multilayer particle in a solvent (E1), it is preferable to disperse them uniformly.

The dispersing method is not particularly restricted, but methods using conventional homogenizers, methods in which dispersion is achieved using an ultrasonic wave, and the like are preferred.

Any solvent can be used as the solvent (E1) without any particular limitations unless it absorbs pulse laser. For example, water and generally commercially available organic solvents {e.g., acetone, methyl ethyl ketone, methanol, ethanol, toluene, xylene, hexane, dioxane, THF, DMF, and DMSO} can be used.

The content (% by weight) of the central layer (L0) or the multilayer particle is preferably from 0.001 to 10, more preferably from 0.005 to 5 based on the weight of the dispersion liquid (D0) or the dispersion liquid (Dn).

The lump of a resin or a metal oxide is preferably placed on the bottom or side face of the container containing the dispersion liquid (D0) or the dispersion liquid (Dn).

The wavelength (nm) of the pulse laser is preferably from 200 to 700, and more preferably is a wavelength such that the pulse laser is not absorbed by the solvent.

The output power (mJ/pulse) of the pulse laser is preferably from 30 to 100.

There are no limitations with the apparatus for oscillating the pulse laser, but a YAG laser oscillator is preferred.

In the application of pulse laser, the temperature (° C.) of the dispersion liquid (D0) or the dispersion liquid (Dn) is preferably from 5 to 80.

The volume of the dispersion liquid (D0) or the dispersion liquid (Dn) is preferably from 10 to 100 ml for one pulse laser oscillator.

The amount (% by volume) of the lump of a resin or a metal oxide used is preferably from 1 to 10 based on the volume of the dispersion liquid (D0) or the dispersion liquid (Dn).

Fine particles are generated from the lump having been irradiated with pulse laser and the fine particles adhere to the surface of the central layer (L0) or the multilayer particle and thereby a resin layer (R) or a metal oxide layer (M) is formed.

The multilayer particle on which the resin layer (R) or the metal oxide layer (M) has been formed is isolated by centrifugal separation, filtration under reduced pressure, pressure filtration, freeze-drying, or the like.

### 1-2. Production Step (20)

Production step (20) includes obtaining a two-layer particle by reacting a central layer (L0) having a reactive group (a) and a gaseous metal compound together by heating to form a metal compound layer on the surface of the central layer (L0) and thereby obtain a metal compound layer particle, then removing the unreacted gaseous metal compound, and reacting the metal compound layer particle and water vapor together to change the metal compound layer into a metal oxide layer (M).

A multilayer structured particle can be obtained by subsequently combining production steps (10), (30) and/or (40). On the other hand, three-layer particles can be obtained by reacting a two-layer particle with a gaseous metal compound and conducting operations in the same manner as described above. Repetition of such operations can afford a multilayer structured particle. Further, a multilayer structured particle can be obtained by reacting the multilayer particles having been obtained through the production steps (10), (30) and/or (40) and a gaseous metal compound and conducting operations in the same manner as described above. In repetition of the operations mentioned above, either gaseous metal compounds of the same kind as the compound used first or different kinds of compounds may be used.

The reactive group (a) is not particularly restricted if it can react with a gaseous metal compound. However, groups having active hydrogen are preferable; a hydroxyl group, a carboxy group, and an amino group are more preferable.

The gaseous metal compound is not particularly restricted if it can react with the reactive group (a). However, titanium halides {e.g., titanium chloride}, alkyl aluminums {e.g., trimethyl aluminum}, and silicon halides {e.g., silicon chloride} are preferable.

The reaction vessel is preferably a heat-resistant and pressure-resistant vessel, and more preferably is a vessel which is equipped with a heating device, an inlet of gases, and a pressure reducing device and which is made of a material inert to gaseous metal compounds.

From the viewpoint of stability of metal compounds, the reaction vessel preferably contains water in an amount as small as possible, more preferably up to 100 ppm, and particularly preferably up to 10 ppm.

The reaction temperature (° C.) is preferably from 30 to 500.

In order to remove the unreacted metal compound, a method of reducing the pressure in the vessel, a method of purging the vessel with an inert gas (e.g., a nitrogen gas or a helium gas) can, for example, be used.

The temperature (° C.) of the reaction between the metal compound layer and water vapor is preferably from 30 to 500.

A layer with a thickness of about 0.2 nm is formed in one cycle of production step (20) and it is possible to achieve a desired thickness by repeating production step (20) using the same kind of metal compound.

Therefore, in the case of using production step (20), it is preferable to repeat such production step (20) twice or more until a predetermined thickness is achieved.

### 1-3. Production Step (30)

Production step (30) includes at least one step selected from step (31), step (32), step (33), and step (34).

That is, the production method including production step (30) includes at least two steps, repetition of at least two steps or repetition of at least one step selected from step (31), step (32), step (33) and step (34), or a combination of these steps and production steps (10), (20) and/or (40). In the case of repeating step (32) and/or step (33), because of alternate use of reactive surfactants having opposite ionicities, it is necessary to obtain a multilayer particle dispersion liquid, followed by isolation {for example, centrifugal separation, filtration under reduced pressure, pressure filtration, or freeze-drying} of the multilayer particles, and then continue to the next step. On the other hand, in the case of repeating step (31) and/or step (34), it is not necessary to isolate the multilayer particles after obtaining a multilayer particle dispersion liquid, but it is preferable to conduct isolation {for example, centrifugal separation, filtration under reduced pressure, pressure filtration, or freeze-drying} and then continue to the next step.

### 1-3-1. Step (31)

The active hydrogen includes a hydrogen atom contained in a hydroxyl group, a carboxy group, an amino group, or a mercapto group.

Alcohols having from 1 to 4 carbon atom(s) include methanol, ethanol, isopropanol, propanol, and butanol. Among these, ethanol and isopropanol are preferred.

Aprotic solvents include ketones {e.g., acetone and methyl ethyl ketone}, esters {e.g., ethyl acetate and butyl acetate}. Among these, methyl ethyl ketone, ethyl acetate, and butyl acetate are preferred.

The concentration (% by volume) of the central layer (L0) or the multilayer particle is preferably from 0.01 to 10, more preferably from 0.02 to 8 based on the volume of the dispersion liquid (D0) or the dispersion liquid (Dn). If it is within such ranges, the standard deviation of the thickness of a layer will be better.

Regarding the dispersion of the central layer (L0) or the multilayer particle in an alcohol or an aprotic solvent (E31), it is preferable to disperse them uniformly.

The dispersing method is not particularly restricted, but methods using conventional homogenizers, methods in which dispersion is achieved using an ultrasonic wave, and the like are preferred.

Examples of the metal alkoxide include alkoxides {1 to 4 carbon atom(s): e.g., methoxide, ethoxide, propoxide, isopropoxide or n-butoxide} of alkali metals {e.g., lithium, sodium and potassium}, alkaline earth metals {e.g., magnesium and calcium}, heavy metals {e.g., titanium, zirconium, iron and copper}, aluminum or silicon. Among these, alkoxides of heavy metals, aluminum, or silicon are preferred.

As the sol-gel method, conventional methods {e.g., a method in which a small amount of hydrochloric acid is added to a dispersion liquid (D0) or a dispersion liquid (Dn) and then a metal alkoxide is further added, followed by a reaction} can be used.

The reaction temperature (° C.) is preferably from 5 to 150, and more preferably from 10 to 80.

It is preferable to use a catalyst in the reaction.

Examples of the catalyst include metal catalysts {e.g., tin catalysts (e.g., dibutyltin dilaurate, stannous octoate, stannous chloride, and tetrabutyl zirconate), and lead catalysts (e.g., lead oleate, lead naphthenate, and lead octenate)}, amine catalysts {e.g., triethylenediamine and dimethylethanolamine}, acid catalysts {e.g., boron trifluoride, hydrochloric acid, paratoluene sulfonic acid, and dodecylbenzenesulfonic acid}, base catalysts {e.g., amines, and alkali earth metal hydroxides}, salts {e.g., quaternary onium salts} and the like.

There is active hydrogen in the metal oxide layer formed through step (31). Therefore, following step (31), step (31) or step (34) may be used.

### 1-3-2. Step (32)

The reactive surfactant (S1) is not particularly restricted if it is a cationic or anionic surfactant having a group copolymerizable with a resin precursor (m).

Examples of the group copolymerizable with a precursor (m) include a vinyl group, an isocyanato group, a blocked isocyanato group, a glycidyl group, an amino group, a hydroxyl group, a carboxy group and the like.

Preferable examples of the anionic reactive surfactant include sodium salts of alkyl(C12-13) allyl diesters of sulfosuccinic acid {e.g., ELEMINOL JS-2: produced by Sanyo Chemical Industries, Ltd. (“ELEMINOL” is a registered trademark of the company.)}, sulfonic acid ester sodium salts of polyoxyalkylene methacrylate {e.g., ELEMINOL RS-30: produced by Sanyo Chemical Industries, Ltd.}, sulfuric acid ester ammonium salts of allyloxymethyl polyoxyethylenehydroxyalkyl ethers {Aqualon KH-10: produced by Dai-Ichi Kogyo Seiyaku Co., Ltd. (“Aqualon” is a registered trademark of the company.)}, and the like.

Preferable examples of the cationic reactive surfactant include compounds having a methacryloxy group and a trialkylammonio group in the same molecule {methacryloxyethylaminocarbonyloxyethyltrimethylammonium methosulfate}, trimethylammonioethyl methacrylate chloride (literature; 13th Polymer Microsphere Symposium, 2B10, Seiko Epson), and the like.

The amount (% by weight) of the reactive surfactant (S1) used is preferably from 1 to 100, and more preferably from 1.5 to 80, based on the weight of the resin precursor (m). If it is within such ranges, the standard deviation of the thickness of a layer will be better.

The surface of the multilayer particle or the central layer (L0) preferably has a charge (q), and more preferably has a zeta potential of 0.1 mV or more, or a zeta potential of −0.1 mV or less.

It is desirable that the charge (q) and the ionicity of the reactive surfactant (S1) are of different signs. For example, when the charge (q) is negative, the reactive surfactant is preferably cationic. On the other hand, for example, when the charge (q) is positive, the reactive surfactant is preferably anionic.

The multilayer particle or the central layer (L0) having a charge (q) preferably has an ionic group on its surface. Examples of the ionic group include anion groups {e.g., a carboxylate group (—CO₂⁻), a phosphonate group (—PO(O⁻)₂, or —PO(OH)(O⁻)), and a sulfonate group (—SO₃⁻)} and cation groups {e.g., an ammonio group (—NH₃⁺), a quaternary ammonio group (—NR₃⁺: R is, at each occurrence, a hydrocarbon group having 1 to 3 carbon atom(s)), a sulfonio group (—SH₂⁺), and a phosphonio group (—PH₃⁺)}.

In the dispersion liquid containing the reactive surfactant (S1) and the multilayer particle or the central layer (L0), water, an alcohol having 4 or less carbon atoms, or the like is used as a dispersion solvent.

Regarding the dispersion of the central layer (L0) or the multilayer particle in the dispersion solvent, it is preferable to disperse them uniformly.

The dispersing method is not particularly restricted, but methods using conventional homogenizers, methods in which dispersion is achieved using an ultrasonic wave, and the like are preferred.

The content (% by volume) of the central layer (L0) or the multilayer particle in the dispersion liquid is preferably from 0.01 to 50 based on the volume of the dispersion liquid.

The reactive surfactant (S2) is not particularly restricted if it is a surfactant having a group copolymerizable with a resin precursor (m) and having an ionicity opposite to that of the reactive surfactant (S1).

If the reactive surfactant (S1) is anionic, the reactive surfactant (S2) is cationic; on the other hand, if the reactive surfactant (S1) is cationic, the reactive surfactant (S2) is anionic.

Examples of the group to be copolymerized with a precursor (m) include a vinyl group, an isocyanato group, a blocked isocyanato group, a glycidyl group, an amino group, a hydroxyl group, a carboxy group and the like.

Examples of the reactive surfactant (S2) include surfactants provided as examples of the reactive surfactant (S1).

The weight ratio {(S1)/(S2)} of the reactive surfactant (S1) used to the reactive surfactant (S2) used is preferably from 1/2 to 2/1.

The resin precursor (m) may be any precursor if it is one which reacts to change into a resin. Examples thereof include a vinyl monomer, glycidyl group-containing compounds, and the like.

The amount (% by volume) of the resin precursor (m) used is preferably from 0.1 to 10 based on the volume of the multilayer particle or the volume of the central layer (L0) because it is related directly to the thickness of the resin layer. If it is within such ranges, the standard deviation of the thickness of a layer will be better.

As a method of copolymerizing the reactive surfactant (S1), the reactive surfactant (S2) and the resin precursor (m), conventional methods can be used. A method using heat, ultraviolet irradiation (UV), or electron beam irradiation (EB) is preferred and a method using heat is more preferred.

In the case of using heat, the reaction temperature (° C.) is preferably from 30 to 160.

Step (32) is a step in which a double micell layer is formed on the surface of a multilayer particle or a central layer (L0) to enclose a precursor (m) therein and then a reactive surfactant (S1), a reactive surfactant (S2), and the precursor (m) are copolymerized to form a resin layer.

### 1-3-3. Step (33)

Step (33) is the same as step (32) except changing “a multilayer particle having a metal oxide layer on its surface or a central layer (L0) composed of a metal oxide” to “a multilayer particle having a resin layer on its surface or a central layer (L0) composed of a resin.”

### 1-3-4. Step (34)

Step (34) is the same as step (31) except changing “a central layer (L0) of a resin having active hydrogen” or “a multilayer particle having a surface composed of a resin layer having active hydrogen” to “a central layer (L0) of a metal oxide having active hydrogen” or “a multilayer particle having a surface composed of a metal oxide layer having active hydrogen.”

1-4. Production step (40)

Step (40) is a step of obtaining a multilayer structured particle preferably by isolating a multilayer particle after step (31) or step (34).

A multilayer structured particle can be obtained by subsequently combining production steps (10), (20) and/or (30). Further, a multilayer structured particle can be obtained by using the multilayer particle having been obtained through the production steps (10), (20) and/or (30) and conducting operations in the same manner as described above. In repetition of the operations mentioned above, either a metal alkoxide of the same kind as the compound used first or different kinds of compounds may be used.

### 2. Production Method (2)

### 2-1. Production Step (50)

Production step (50) is a step of obtaining a multilayer structured particle by isolating a multilayer particle after step (33) and then repeating step (33).

### 2-2. Production Step (60)

The central layer (L0) being composed of a resin and having a charge (q) on its surface preferably has an ionic group on its surface, which is the same as that in step (32).

The charge (q) is preferably a zeta potential of 0.1 mV or more, or a zeta potential of −0.1 mV or less.

Water, an alcohol having 4 or less carbon atoms, or the like is used as the dispersion solvent of the dispersion liquid.

Regarding the dispersion of the central layer (L0) or the multilayer particle in the dispersion solvent, it is preferable to disperse them uniformly.

The dispersing method is not particularly restricted, but methods using conventional homogenizers, methods in which dispersion is achieved using an ultrasonic wave, and the like are preferred.

The content (% by volume) of the central layer (L0) or the multilayer particle in the dispersion liquid is preferably from 0.01 to 50, and more preferably from 0.02 to 40, based on the volume of the dispersion liquid.

The resin particle (P0) is not particularly restricted if it has a charge (r) opposite to the charge (q) and has a particle diameter as small as 1/10 of the particle diameter of the central layer (L0) or the multilayer particle.

The resin particle (P0) is obtained by a general method, such as emulsion polymerization, suspension polymerization, miniemulsion polymerization, or dispersion polymerization. Among these, emulsion polymerization is preferred from the viewpoint of particle size control.

The volume mean particle diameter (μm) of the central layer (L0) or the multilayer particle is preferably from 0.1 to 20.

The volume mean particle diameter (μm) of the resin particle (P0) is preferably from 0.01 to 2, and more preferably from 0.02 to 1.

The content (% by volume) of the central layer (L0) or the multilayer particle is preferably from 0.01 to 50 based on the volume of the dispersion liquid.

The content (% by weight) of the resin particle (P0) is preferably from 0.1 to 100, more preferably from 5 to 100 based on the weight of the central layer (L0) or the multilayer particle.

At the time of adding the resin particle (P0) to the dispersion liquid (Dn), the temperatures of the dispersion liquid (Dn) and the resin particle (P0) are preferably from 5 to 40° C.

The multilayer particle on which a resin layer has been formed is preferably isolated by centrifugal separation, filtration under reduced pressure, pressure filtration, freeze-drying, or the like. The same operation is repeated using this dispersion liquid (preferably, a multilayer particle isolated) and, as a result, a multilayer structured particle is produced.

### 3. Another Production Method (3)

The multilayer structured particle of the present invention can be produced not only by the production methods described above but also by the following known methods if a central layer (L0) is provided as a core and two or more layers (Ln) can be disposed concentrically with respect to the center of the core.

### 3-1. Production Step (70)

A production method in which a multilayer structured particle is obtained by dissolving block polymers having different solubility parameters in an organic solvent, dispersing the solution in water using a surfactant, and then removing the solvent.

### 3-2. Production Step (80)

A production method in which a multilayer structured particle is obtained by introducing a vinyl group to a reactive group in the surface of the central layer (L0) or the multilayer particle utilizing a coupling agent or the like, grafting a vinyl monomer, and repeating this operation.

### 3-3. Production Step (90)

A production method in which a multilayer structured particle is obtained by a dry method by colliding a large particle with a small particle at a high speed to form a layer of the small particle on the surface of the large particle, and repeating this operation.

### 3-4. Production Step (100)

A production method in which a multilayer structured particle is obtained by dispersing a large particle and a small particle in a solvent, stirring this solution at a high speed to form a layer of the small particle on the surface of the large particle, and repeating this operation.

Among these production methods, production steps (10) to (60) are preferably included.

Production steps (10) to (100) may be combined.

Examples of such a combination include combinations of steps (10) and (30), steps (20) and (30), steps (30) and (50), steps (30) and (60), steps (20) and (50), and the like. Among these, a combination of steps (10) and (30) and a combination of steps (20) and (30) are preferred from the viewpoint of ease in controlling of the refractive index difference.

The multilayer structured particle of the present invention is applicable to color filters for displays, resin films, coating materials {e.g., colored paints, lusterless paint, and paints for reflection panels and reflection films}, light scattering films, and the like. In addition, it can be used also as a pigment or a dye.

When the multilayer structured particle of the present invention is spherical, it is suited for color filters for displays; when it is non-spherical, it is suited for light scattering films. Both spherical particles and non-spherical particles are suited for resin films and coating materials.

A color filter can be produced, for example, by discharging and arranging a dispersion liquid in which a spherical multilayer structured particle is dispersed {5 to 20% by weight}, a binder, and the like through an ink jet nozzle onto a glass substrate, followed by drying.

A light scattering film and a resin film can be produced by (1) a method comprising melt-kneading a resin for films and a multilayer structured particle, followed by extrusion and stretching, (2) a method comprising dispersing a multilayer structured particle in a resin solution and casting it to form a film, (3) a method comprising dispersing a multilayer structured particle in a monomer, followed by polymerization, or the like.

The content (% by weight) of the multilayer structured particle is preferably from 1 to 80, more preferably from 5 to 50, based on the combined weight of the resin for films and the multilayer structured particle.

Examples of the resin for films include resins for optical applications {e.g., polymethyl methacrylate (PMMA), polycarbonate, and polyester}, binder resins {e.g., a urethane resin, an epoxy resin, an acrylic resin, and polyester}, and the like.

Coating materials can be obtained by mixing raw materials to be used for conventional paints and inks {e.g., binders and solvents} and the multilayer structured particle of the present invention. Attention should be paid not to allow the multilayer structured particle to be broken by shearing stress due to mixing.

### EXAMPLES

While the invention will be further described by way of Examples, it is not limited thereto.

Hereafter, “part(s)” and “%” shall mean “part(s) by weight” and “% by weight,” respectively.

### Production Example 1

### Production of a Cationic Reactive Surfactant

100 parts of 2-(methacryloyloxy)ethyl isocyanate (trade name: Karenz MOI: produced by Showa Denko K.K.; “Karenz” is a registered trademark of the company.}, 57 parts of dimethylaminoethanol, and 1 part of dibutyltin dilaurate were reacted at 80° C. for 8 hours. Thereafter 81 parts of dimethyl sulfate was further added to the resulting solution and then a reaction was effected at 60° C. for 4 hours. Thus, a cationic reactive surfactant (S-1) {methacryloxyethylaminocarbonyloxyethyltrimethylammonium methosulfate} was obtained.

### Production Example 2

### Production of a Titania Spherical Particle (Central Layer)

200 parts of titanium tetraisopropoxide, 750 parts of methyl ethyl ketone, and 7 parts of polyvinyl pyrrolidone (number-average molecular weight: 40000) were mixed uniformly and then heated to 50° C., followed by dropping of 2 parts of 1% aqueous ammonia solution over 1 hour. After the dropping, the mixture was heated to 80° C. and subjected to a reaction for 8 hours. Thus, a dispersion liquid containing a spherical titania particle (LB-1) was obtained. The spherical titania particle (LB-1) {volume mean particle diameter: 2.7 μm; mean circularity: 0.98} was obtained by subjecting the dispersion liquid to centrifugal separation, washing with water, and drying {50° C.×48 hours, in a fair-wind dryer; the same in the following}.

### Production Example 3

A water phase was obtained by uniformly mixing 800 parts of ion exchange water and 5 parts of sodium dodecylbenzenesulfonate. One the other hand, an oil layer was obtained by uniformly mixing 100 parts of styrene, 60 parts of divinylbenzene, 20 parts of hydroxyethyl methacrylate, 5 parts of azobisbutyronitrile, and 15 parts of an anionic reactive surfactant {ELEMINOL JS-2: produced by Sanyo Chemical Industries, Ltd.: “ELEMINOR” is a registered trademark of the company}. Then, the entire portion of the oil layer was added to the waterphase, followed by stirring at 4000 rpm for 1 minute with a rotor-stator disperser [TK homomixer: produced by Tokushu Kika Kogyo Co., Ltd.]. The mixture was transferred to a pressure-resistant vessel equipped with a stirrer and then subjected to a reaction at 85° C. for 12 hours. Thus, a dispersion liquid containing a spherical resin particle (LB-2), which had active hydrogen (hydroxyl group) in its surface, was obtained. The spherical resin particle (LB-2) {volume mean particle diameter: 5.3 μm; mean circularity: 0.98} was obtained by subjecting the dispersion liquid to centrifugal separation, washing with water, and drying.

### Production Example 4

750 parts of methyl ethyl ketone, 7 parts of polyvinyl pyrrolidone (number-average molecular weight: 40000) and 50 parts of spherical resin particle (LB-2) were mixed uniformly and then heated to 50° C., followed by dropping of 2 parts of 1% aqueous ammonia solution over 1 hour. After the dropping of 0.47 parts of tetraethoxysilane over 1 hour, the mixture was heated to 80° C. and subjected to a reaction for 8 hours. Thus, a dispersion liquid containing a two-layer structured spherical particle (LB-3) was obtained. The two-layer structured spherical particle (LB-3) {central layer (L0): crosslinked polystyrene, silica layer (L1), volume mean particle diameter: 5.3 μm, mean circularity: 0.98} was subjected to centrifugal separation, washing with water, and drying.

### Production Example 5

A two-layer structured spherical particle (LB-6) {volume mean particle diameter: 5.3 μm, mean circularity: 0.98} was obtained in the same manner as in Production Example 4 except changing the amount of tetraethoxysilane from “0.47 parts” to “0.55 parts.”

### Production Example 6

A two-layer structured spherical particle (LB-9) {volume mean particle diameter: 5.4 μm, mean circularity: 0.98} was obtained in the same manner as in Production Example 4 except changing the amount of tetraethoxysilane from “0.47 parts” to “0.68 parts.”

### Production Example 7

A mixture of 950 parts of ion exchange water, 45 parts of the spherical titania particle (LB-1), and 1 part of sodium dodecylbenzenesulfonate was irradiated with an ultrasonic wave for 30 minutes to yield a dispersion liquid. 70 ml of this dispersion liquid was charged into a chamber (capacity: 100 ml) of a submerged-type laser ablation system [produced by Nara Machinery Co., Ltd.]. Two grams of a polytetrafluoroethylene lump was set in the dispersion liquid and this lump was irradiated with laser (condition wavelength: 270 nm, output power: 60 mJ/pulse) for 15 minutes. Thus, polytetrafluoroethylene was vapor-deposited on the surface of the spherical titania particle (LB-1). The two-layer structured spherical particle (LB-12) {volume mean particle diameter: 2.7 μm; mean circularity: 0.98} was obtained by subjecting the dispersion liquid in the chamber to centrifugal separation, washing with water, and drying.

### Production Example 8

A two-layer structured spherical particle (LB-15) {volume mean particle diameter: 2.7 μm, mean circularity: 0.98} was obtained in the same manner as in Production Example 7 except changing the laser irradiation time from “15 minutes” to “20 minutes.”

### Production Example 9

A two-layer structured spherical particle (LB-18) {volume mean particle diameter: 2.7 μm, mean circularity: 0.98} was obtained in the same manner as in Production Example 7 except changing the laser irradiation time from “15 minutes” to “30 minutes.”

### Production Example 10

(1) 50 parts of the spherical titania particle (LB-1) was placed in a pressure-reducible vessel. The vessel was heated to 100° C. and the pressure was reduced to −0.2 MPa and held for 20 minutes.

(2) The pressure in the vessel was adjusted to −0.05 MPa with a nitrogen gas (99.999%), and trimethylaluminum was charged until the pressure in the vessel became 0 MPa. After holding at 100° C. for 1 minute, the pressure was reduced again to −0.2 MPa. After adjusting the pressure to 0 MPa with a nitrogen gas, the pressure was reduced to −0.2 MPa and then to −0.05 MPa with a nitrogen gas. Subsequently, water vapor was charged until the pressure in the vessel became 0 MPa. After holding at 100° C. for 5 minutes, the pressure was reduced again to −0.2 MPa.

(3) A titania-alumina two-layer structured spherical particle (LB-21) {volume mean particle diameter: 2.7 μm, mean circularity 0.98} was obtained by repeating operation (2) 135 times and then cooling.

### Production Example 11

A two-layer structured spherical particle (LB-24) {volume mean particle diameter: 2.7 μm, mean circularity: 0.98} was obtained in the same manner as in Production Example 10 except changing “repeating operation (2) 135 times” to “repeating operation (2) 165 times.”

### Production Example 12

A two-layer structured spherical particle (LB-27) {volume mean particle diameter: 2.7 μm, mean circularity: 0.98} was obtained in the same manner as in Production Example 10 except changing “repeating operation (2) 135 times” to “repeating operation (2) 190 times.”

### Production Example 13

A water phase was obtained by uniformly mixing 800 parts of ion exchange water and 5 parts of sodium dodecylbenzenesulfonate. On the other hand, an oil layer was obtained by uniformly mixing 180 parts of styrene, 5 parts of azobisbutyronitrile, and 15 parts of an anionic reactive surfactant {ELEMINOL JS-2: produced by Sanyo Chemical Industries, Ltd.}. Then, the entire portion of the oil layer was added to the water phase, followed by stirring at 4000 rpm for 1 minute with a rotor-stator disperser [TK homomixer: produced by Tokushu Kika Kogyo Co., Ltd.]. The mixture was transferred to a pressure-resistant vessel equipped with a stirrer and then subjected to a reaction at 85° C. for 12 hours. Thus, a dispersion liquid containing a spherical resin particle (LB-30) was obtained. The spherical resin particle (LB-30) {volume mean particle diameter: 5.3 μm; mean circularity: 0.98} was obtained by subjecting this dispersion liquid to centrifugal separation, washing with water, and drying.

### Production Example 14

A dispersion liquid was obtained by irradiating a mixed liquid of 900 parts of ion exchange water and 50 parts of the spherical resin particle (LB-30) with an ultrasonic wave for 30 minutes, and then adding 3 parts of a cationic reactive surfactant (S-1) and stirring for 4 hours. On the other hand, after uniformly mixing 0.47 parts of methyl methacrylate, 0.03 parts of an anionic reactive surfactant [ELEMINOL JS-2: produced by Sanyo Chemical Industries, Ltd.], and 0.01 parts of azobisbutyronitrile, the mixed liquid was added to the dispersion liquid, followed by stirring for 30 minutes. Thus, a mixed dispersion liquid was obtained. The mixed dispersion liquid was transferred to a pressure-resistant vessel equipped with a stirrer and subjected to a reaction at 85° C. for 12 hours. Thus, a dispersion liquid containing a two-layer structured spherical particle (LB-31) was obtained. The two-layer structured spherical particle (LB-31) {volume mean particle diameter: 5.3 μm; mean circularity: 0.98} was obtained by subjecting the dispersion liquid to centrifugal separation, washing with water, and drying.

### Production Example 15

A two-layer structured spherical particle (LB-34) {volume mean particle diameter: 5.3 μm, mean circularity: 0.98} was obtained in the same manner as in Production Example 14 except changing the amount of methyl methacrylate from “0.47 parts” to “0.55 parts.”

### Production Example 16

A two-layer structured spherical particle (LB-37) {volume mean particle diameter: 5.4 μm, mean circularity: 0.98} was obtained in the same manner as in Production Example 14 except changing the amount of methyl methacrylate from “0.47 parts” to “0.68 parts.”

### Example 1

A dispersion liquid was obtained by uniformly mixing 800 parts of ion exchange water, 0.2 parts of a cationic reactive surfactant (S-1), and 50 parts of the two-layer structured spherical particle (LB-3). On the other hand, an oil layer was obtained by uniformly mixing 0.2 parts of styrene, 0.17 parts of divinylbenzene, 0.1 parts of hydroxyethyl methacrylate, 0.03 parts of azobisbutyronitrile, and 0.2 parts of an anionic reactive surfactant {ELEMINOL JS-2: produced by Sanyo Chemical Industries, Ltd.}. Subsequently, the dispersion liquid was heated to 85° C. After dropping the oil layer to the dispersion liquid over 1 hour under stirring, the mixture was subjected to a reaction for 12 hours. Thus, a dispersion liquid containing a three-layer structured spherical particle (LB-4) was obtained. The three-layer structured spherical particle (LB-4) {three-layer structure: crosslinked polystyrene-silica-crosslinked polystyrene, volume mean particle diameter: 5.4 μm, mean circularity: 0.98} was obtained by subjecting the dispersion liquid to centrifugal separation, washing with water, and drying.

### Example 2

A four-layer structured spherical particle was obtained in the same manner as in Production Example 4 except changing “spherical resin particle (LB-2)” to “three-layer structured spherical particle (LB-4).” Then, a five-layer structured spherical particle was obtained in the same manner as in Example 1 except changing “two-layer structured spherical particle (LB-3)” to “four-layer structured spherical particle.” Then, a 23-layer structured spherical particle (LB-5) having a crosslinked polystyrene layer-a silica layer structure {volume mean particle diameter: 10.2 μm, mean circularity: 0.99} was obtained by repeating one after another in the same manners as in Production Example 4 and Example 1 except changing “multilayer structured spherical particle.”

### Example 3

A three-layer structured spherical particle (LB-7) {volume mean particle diameter: 5.4 μm, mean circularity: 0.98} was obtained in the same manner as in Example 1 except changing “two-layer structured spherical particle (LB-3)” to “two-layer structured spherical particle (LB-6)”, changing the amount of styrene from “0.2 parts” to “0.24 parts”, changing the amount of divinylbenzene from “0.17 parts” to “0.20 parts”, and changing the amount of dihydroxyethyl methacrylate from “0.1 parts” to “0.11 parts.”

### Example 4

A four-layer structured spherical particle was obtained in the same manner as in Production Example 5 except changing “two-layer structured spherical particle (LB-3)” to “three-layer structured spherical particle (LB-7).” Then, a five-layer structured spherical particle was obtained in the same manner as in Example 1 except changing “two-layer structured spherical particle (LB-3)” to “four-layer structured spherical particle”, changing the amount of styrene from “0.2 parts” to “0.24 parts”, changing the amount of divinylbenzene from “0.17 parts” to “0.20 parts”, and changing the amount of hydroxyethyl methacrylate from “0.1 parts” to “0.11 parts.” Then, a 23-layer structured spherical particle (LB-8) {volume mean particle diameter: 11.2 μm, mean circularity: 0.99} was obtained by repeating one after another in the same manners as Production Example 5 and Example 1 except changing “multilayer structured spherical particle” and changing the amounts of styrene, divinylbenzene and hydroxyethyl methacrylate as mentioned above.

### Example 5

A three-layer structured spherical particle (LB-10) {volume mean particle diameter: 5.6 μm, mean circularity: 0.98} was obtained in the same manner as in Example 1 except changing “two-layer structured spherical particle (LB-3)” to “two-layer structured spherical particle (LB-9)”, changing the amount of styrene from “0.2 parts” to “0.29 parts”, changing the amount of divinylbenzene from “0.17 parts” to “0.24 parts”, and changing the amount of hydroxyethyl methacrylate from “0.1 parts” to “0.15 parts.”

### Example 6

A four-layer structured spherical particle was obtained in the same manner as in Production Example 6 except changing “two-layer structured spherical particle (LB-3)” to “three-layer structured spherical particle (LB-10).” Then, a five-layer structured spherical particle was obtained in the same manner as in Example 1 except changing “two-layer structured spherical particle (LB-3)” to “four-layer structured spherical particle”, changing the amount of styrene from “0.2 parts” to “0.29 parts”, changing the amount of divinylbenzene from “0.17 parts” to “0.24 parts”, and changing the amount of hydroxyethyl methacrylate from “0.1 parts” to “0.15 parts.” Then, a 23-layer structured spherical particle (LB-11) {volume mean particle diameter: 12.2 μm, mean circularity: 0.99} was obtained by repeating one after another in the same manners as Production Example 6 and Example 1 except changing “multilayer structured spherical particle” and changing the amounts of styrene, divinylbenzene and hydroxyethyl methacrylate as mentioned above.

### Example 7

A three-layer structured spherical particle (LB-13) {volume mean particle diameter: 2.7 μm, mean circularity: 0.98} was obtained in the same manner as in Production Example 7 except changing “spherical titania particle (LB-1)” to “two-layer structured spherical particle (LB-12)” and changing “polytetrafluoroethylene” to “titania.”

### Example 8

A four-layer structured spherical particle was obtained in the same manner as in Production Example 7 except changing “spherical titania particle (LB-1)” to “three-layer structured spherical particle (LB-13).” Then, a five-layer structured spherical particle was obtained in the same manner as in Production Example 7 except changing “spherical titania particle (LB-1)” to “four-layer structured spherical particle” and changing “polytetrafluoroethylene” to “titania.” Then, a ten-layer structured spherical particle (LB-14) having alternately disposed titania layers-polytetrafluoroethylene layers {volume mean particle diameter: 3.1 μm, mean circularity: 0.99} was obtained by repeating the same operations as those in Production Example 7 except changing “multilayer structured spherical particle” and changing “polytetrafluoroethylene” and “titania” to one after another.

### Example 9

A three-layer structured spherical particle (LB-16) {volume mean particle diameter: 2.8 μm, mean circularity: 0.98} was obtained in the same manner as in Production Example 7 except changing “spherical titania particle (LB-1)” to “two-layer structured spherical particle (LB-15)”, changing “polytetrafluoroethylene” to “titania” and changing the laser irradiation time from “15 minutes” to “20 minutes.”

### Example 10

A four-layer structured spherical particle was obtained in the same manner as in Production Example 7 except changing “spherical titania particle (LB-1)” to “three-layer structured spherical particle (LB-16)” and changing the laser irradiation time from “15 minutes” to “20 minutes.” Then, a five-layer structured spherical particle was obtained in the same manner as in Production Example 7 except changing “spherical titania particle (LB-1)” to “four-layer structured spherical particle”, changing “polytetrafluoroethylene” to “titania” and changing the laser irradiation time from “15 minutes” to “20 minutes.” Then, a ten-layer structured spherical particle (LB-17) {volume mean particle diameter: 3.5 μm, mean circularity: 0.99} was obtained by repeating the same operations as those in Production Example 7 except changing “multilayer structured spherical particle”, changing the laser irradiation time from “15 minutes” to “20 minutes” and changing “polytetrafluoroethylene” and “titania” to one after another.

### Example 11

A three-layer structured spherical particle (LB-19) {volume mean particle diameter: 2.9 μm, mean circularity: 0.98} was obtained in the same manner as in Production Example 7 except changing “spherical titania particle (LB-1)” to “two-layer structured spherical particle (LB-18)”, changing “polytetrafluoroethylene” to “titania” and changing the laser irradiation time from “15 minutes” to “30 minutes.”

### Example 12

A four-layer structured spherical particle was obtained in the same manner as in Production Example 7 except changing “spherical titania particle (LB-1)” to “three-layer structured spherical particle (LB-19)” and changing the laser irradiation time from “15 minutes” to “30 minutes.” Then, a five-layer structured spherical particle was obtained in the same manner as in Production Example 7 except changing “spherical titania particle (LB-1)” to “four-layer structured spherical particle”, changing “polytetrafluoroethylene” to “titania” and changing the laser irradiation time from “15 minutes” to “30 minutes.” Then, a ten-layer structured spherical particle (LB-20) {volume mean particle diameter: 4.0 μm, mean circularity: 0.99} was obtained by repeating the same operations as those in Production Example 7 except changing “multilayer structured spherical particle”, changing the laser irradiation time from “15 minutes” to “30 minutes” and changing “polytetrafluoroethylene” and “titania” to one after another.

### Example 13

A three-layer structured spherical particle (LB-22) having a titania layer-alumina layer-titania layer structure {volume mean particle diameter: 2.7 μm, mean circularity: 0.98} was obtained in the same manner as in Production Example 10 except changing “spherical titania particle (LB-1)” to “two-layer structured spherical particle (LB-21)” and changing “trimethylaluminum” to “titania chloride.”

### Example 14

A four-layer structured spherical particle was obtained in the same manner as in Production Example 10 except changing “spherical titania particle (LB-1)” to “three-layer structured spherical particle (LB-22).” Then, a five-layer structured spherical particle was obtained in the same manner as in Production Example 10 except changing “spherical titania particle (LB-1)” to “four-layer structured spherical particle” and changing “trimethylaluminum” to “titania chloride.” Then, a ten-layer structured spherical particle (LB-23) {volume mean particle diameter: 3.1 μm, mean circularity: 0.98} was obtained by repeating the same operations as those in Production Example 10 except changing “multilayer structured spherical particle” and changing “trimethylaluminum” and “titania chloride” to one after another.

### Example 15

A three-layer structured spherical particle (LB-25) {volume mean particle diameter: 2.8 μm, mean circularity: 0.98} was obtained in the same manner as in Production Example 10 except changing “spherical titania particle (LB-1)” to “two-layer structured spherical particle (LB-24)”, changing “trimethylaluminum” to “titania chloride” and changing “repeating operation (2) 135 times” to “repeating operation (2) 165 times.”

### Example 16

A four-layer structured spherical particle was obtained in the same manner as in Production Example 10 except changing “spherical titania particle (LB-1)” to “three-layer structured spherical particle (LB-25)” and changing “repeating operation (2) 135 times” to “repeating operation (2) 165 times.” Then, a five-layer structured spherical particle was obtained in the same manner as in Production Example 10 except changing “spherical titania particle (LB-1)” to “four-layer structured spherical particle”, changing “trimethylaluminum” to “titania chloride” and changing “repeating operation (2) 135 times” to “repeating operation (2) 165 times.” Then, a ten-layer structured spherical particle (LB-26) {volume mean particle diameter: 3.5 μm, mean circularity: 0.99} was obtained by repeating the same operations as those in Production Example 10 except changing “multilayer structured spherical particle” and changing “trimethylaluminum” and “titania chloride” to one after another.

### Example 17

A three-layer structured spherical particle (LB-28) {volume mean particle diameter: 2.9 μm, mean circularity: 0.98} was obtained in the same manner as in Production Example 10 except changing “spherical titania particle (LB-1)” to “two-layer structured spherical particle (LB-27)”, changing “trimethylaluminum” to “titania chloride” and changing “repeating operation (2) 135 times” to “repeating operation (2) 190 times.”

### Example 18

A four-layer structured spherical particle was obtained in the same manner as in Production Example 10 except changing “spherical titania particle (LB-1)” to “three-layer structured spherical particle (LB-28)” and changing “repeating operation (2) 135 times” to “repeating operation (2) 190 times.” Then, a five-layer structured spherical particle was obtained in the same manner as in Production Example 10 except changing “spherical titania particle (LB-1)” to “four-layer structured spherical particle”, changing “trimethylaluminum” to “titania chloride” and changing “repeating operation (2) 135 times” to “repeating operation (2) 190 times.” Then, a ten-layer structured spherical particle (LB-29) {volume mean particle diameter: 4.0 μm, mean circularity: 0.99} was obtained by repeating the same operations as those in Production Example 10 except changing “multilayer structured spherical particle” and changing “trimethylaluminum” and “titania chloride” to one after another.

### Example 19

A three-layer structured spherical particle (LB-32) having a polystyrene layer-polymethyl methacrylate layer-polystyrene layer structure {volume mean particle diameter: 5.4 μm, mean circularity: 0.98} was obtained in the same manner as in Production Example 14 except changing “spherical resin particle (LB-30)” to “two-layer structured spherical particle (LB-31)” and changing “methyl methacrylate” to “styrene.”

### Example 20

A four-layer structured spherical particle was obtained in the same manner as in Production Example 14 except changing “spherical resin particle (LB-30)” to “three-layer structured spherical particle (LB-32).” Then, a five-layer structured spherical particle was obtained in the same manner as in Production Example 14 except changing “spherical resin particle (LB-30)” to “four-layer structured spherical particle” and changing “methyl methacrylate” to “styrene.” Then, a 23-layer structured spherical particle (LB-33) {volume mean particle diameter: 10.2 μm, mean circularity: 0.99} was obtained by repeating the same operations as those in Production Example except changing “multilayer structured spherical particle” and changing “methyl methacrylate” and “styrene” to one after another.

### Example 21

A three-layer structured spherical particle (LB-35) {volume mean particle diameter: 5.4 μm, mean circularity: 0.98} was obtained in the same manner as in Production Example 14 except changing “spherical resin particle (LB-30)” to “two-layer structured spherical particle (LB-34)” and changing “0.47 parts of methyl methacrylate” to “0.55 parts of styrene.”

### Example 22

A four-layer structured spherical particle was obtained in the same manner as in Production Example 14 except changing “spherical resin particle (LB-30)” to “three-layer structured spherical particle (LB-35)” and changing the amount of methyl methacrylate from “0.47 parts” to “0.55 parts.” Then, a five-layer structured spherical particle was obtained in the same manner as in Production Example 14 except changing “spherical resin particle (LB-30)” to “four-layer structured spherical particle” and changing “0.47 parts of methyl methacrylate” to “0.55 parts of styrene.” Then, a 23-layer structured spherical particle (LB-36) {volume mean particle diameter: 11.2 μm, mean circularity: 0.99} was obtained by repeating operations alternately in the same manner as in Production Example 14 except changing “multilayer structured spherical particle” and changing the amounts of methyl methacrylate and styrene as mentioned above.

### Example 23

A three-layer structured spherical particle (LB-38) {volume mean particle diameter: 5.6 μm, mean circularity: 0.98} was obtained in the same manner as in Production Example 14 except changing “spherical resin particle (LB-30)” to “two-layer structured spherical particle (LB-37)” and changing “0.47 parts of methyl methacrylate” to “0.68 parts of styrene.”

### Example 24

A four-layer structured spherical particle was obtained in the same manner as in Production Example 14 except changing “spherical resin particle (LB-30)” to “three-layer structured spherical particle (LB-38)” and changing the amount of methyl methacrylate from “0.47 parts” to “0.55 parts.” Then, a five-layer structured spherical particle was obtained in the same manner as in Production Example 14 except changing “spherical resin particle (LB-30)” to “four-layer structured spherical particle” and changing “0.47 parts of methyl methacrylate” to “0.68 parts of styrene.” Then, a 23-layer structured spherical particle (LB-39) {volume mean particle diameter: 12.2 μm, mean circularity: 0.99} was obtained by repeating operations alternately in the same manner as in Production Example 14 except changing “multilayer structured spherical particle” and changing the amounts of methyl methacrylate and styrene as mentioned above.

For the multilayer structured particles obtained in Examples 1 to 24, the number (n) of layers, the volume mean particle diameter, the mean circularity, the refractive index of each layer, and the volume of the central layer (L0) are shown in Tables 1 to 4.

TABLE 1

| | | Example | | | | | |
|---|---|---|---|---|---|---|---|
| | | 1 | 2 | 3 | 4 | 5 | 6 |
| Multilayer structured particle | | LB-4 | LB-5 | LB-7 | LB-8 | LB-10 | LB-11 |
| Number of layers | | 3 | 23 | 3 | 23 | 3 | 23 |
| Volume mean particle diameter (μm) | | 5.4 | 10.2 | 5.4 | 11.2 | 5.6 | 12.2 |
| Mean circularity | | 0.98 | 0.99 | 0.98 | 0.99 | 0.98 | 0.99 |
| Mean layer thickness (μm) | | 0.048 | 0.049 | 0.059 | 0.058 | 0.069 | 0.067 |
| % by volume of central layer (L0) | | 95 | 14 | 95 | 11 | 85 | 8 |
| Refractive index difference | | 0.09 | 0.09 | 0.09 | 0.09 | 0.09 | 0.09 |
| Silica layer | Refractive index | 1.46 | 1.46 | 1.46 | 1.46 | 1.46 | 1.46 |
| | Mean thickness (μm) | 0.045 | 0.046 | 0.058 | 0.056 | 0.068 | 0.068 |
| | Standard deviation | 8 | 7 | 4 | 4 | 7 | 6 |
| | of thickness (%) | | | | | | |
| Crosslinked | Refractive index | 1.55 | 1.55 | 1.55 | 1.55 | 1.55 | 1.55 |
| polystyrene | Mean thickness (μm) | 0.051 | 0.051 | 0.061 | 0.060 | 0.070 | 0.065 |
| layer | Standard deviation | 22 | 17 | 28 | 20 | 23 | 18 |
| | of thickness (%) | | | | | | |

Notes:
1. The mean thickness and the standard deviation were the same for all silica layers.
2. The mean thickness and the standard deviation were the same for all crosslinked polystyrene layers.
3. The mean layer thickness is the average of all layers.

TABLE 2

| | | Example | | | | | |
|---|---|---|---|---|---|---|---|
| | | 7 | 8 | 9 | 10 | 11 | 12 |
| Multilayer structured particle | | LB-13 | LB-14 | LB-16 | LB-17 | LB-19 | LB-20 |
| Number of layers | | 3 | 10 | 3 | 10 | 3 | 10 |
| Volume mean particle diameter (μm) | | 2.7 | 3.1 | 2.8 | 3.5 | 2.9 | 4 |
| Mean circularity | | 0.98 | 0.99 | 0.98 | 0.99 | 0.98 | 0.99 |
| Mean layer thickness (μm) | | 0.027 | 0.027 | 0.033 | 0.033 | 0.038 | 0.038 |
| % by volume of central layer (L0) | | 97 | 66 | 90 | 46 | 81 | 31 |
| Refractive index difference | | 1.34 | 1.34 | 1.34 | 1.34 | 1.34 | 1.34 |
| Polytetrafluoroethylene | Refractive index | 1.42 | 1.42 | 1.42 | 1.42 | 1.42 | 1.42 |
| layer | Mean thickness | 0.027 | 0.027 | 0.033 | 0.033 | 0.038 | 0.038 |
| | (μm) | | | | | | |
| | Standard deviation | 8 | 9 | 8 | 8 | 7 | 11 |
| | of thickness (%) | | | | | | |
| Titania layer | Refractive index | 2.76 | 2.76 | 2.76 | 2.76 | 2.76 | 2.76 |
| | Mean thickness | 0.027 | 0.027 | 0.033 | 0.033 | 0.038 | 0.038 |
| | (μm) | | | | | | |
| | Standard deviation | 8 | 9 | 8 | 8 | 7 | 7 |
| | of thickness (%) | | | | | | |

Notes:
1. The mean thickness and the standard deviation were the same for all polytetrafluorothylene layers.
2. The mean thickness and the standard deviation were the same for all titania layers.
3. The mean layer thickness is the average of all layers.

TABLE 3

| | | Example | | | | | |
|---|---|---|---|---|---|---|---|
| | | 13 | 14 | 15 | 16 | 17 | 18 |
| Multilayer structured particle | | LB-22 | LB-23 | LB-25 | LB-26 | LB-28 | LB-29 |
| Number of layers | | 3 | 10 | 3 | 10 | 3 | 10 |
| Volume mean particle diameter (μm) | | 2.7 | 3.1 | 2.8 | 3.5 | 2.9 | 4 |
| Mean circularity | | 0.98 | 0.98 | 0.98 | 0.99 | 0.98 | 0.99 |
| Mean layer thickness (μm) | | 0.030 | 0.031 | 0.045 | 0.043 | 0.062 | 0.061 |
| % by volume of central layer (L0) | | 97 | 66 | 90 | 46 | 81 | 31 |
| Refractive index difference | | 1.2 | 1.2 | 1.2 | 1.2 | 1.2 | 1.2 |
| Alumina | Refractive index | 1.56 | 1.56 | 1.56 | 1.56 | 1.56 | 1.56 |
| layer | Mean thickness (μm) | 0.030 | 0.031 | 0.045 | 0.043 | 0.062 | 0.061 |
| | Standard deviation of | 5 | 3 | 4 | 3 | 6 | 2 |
| | thickness (%) | | | | | | |
| Titania | Refractive index | 2.76 | 2.76 | 2.76 | 2.76 | 2.76 | 2.76 |
| layer | Mean thickness (μm) | 0.030 | 0.031 | 0.045 | 0.043 | 0.062 | 0.061 |
| | Standard deviation of | 5 | 3 | 4 | 3 | 6 | 2 |
| | thickness (%) | | | | | | |

Notes:
1. The mean thickness and the standard deviation were the same for all alumina layers.
2. The mean thickness and the standard deviation were the same for all titania layers.
3. The mean layer thickness is the average of all layers.

TABLE 4

| | | Example | | | | | |
|---|---|---|---|---|---|---|---|
| | | 19 | 20 | 21 | 22 | 23 | 24 |
| Multilayer structured particle | | LB-32 | LB-33 | LB-35 | LB-36 | LB-38 | LB-39 |
| Number of layers | | 3 | 23 | 3 | 23 | 3 | 23 |
| Volume mean particle diameter (μm) | | 5.4 | 10.2 | 5.4 | 11.2 | 5.6 | 12.2 |
| Mean circularity | | 0.98 | 0.99 | 0.99 | 0.99 | 0.98 | 0.99 |
| Mean layer thickness (μm) | | 0.050 | 0.049 | 0.058 | 0.057 | 0.070 | 0.067 |
| % by volume of central layer (L0) | | 95 | 14 | 95 | 11 | 85 | 8 |
| Refractive index difference | | 0.1 | 0.1 | 0.1 | 0.1 | 0.1 | 0.1 |
| Polymethyl | Refractive index | 1.49 | 1.49 | 1.49 | 1.49 | 1.49 | 1.49 |
| methacrylate | Mean thickness (μm) | 0.051 | 0.049 | 0.059 | 0.057 | 0.072 | 0.067 |
| layer | Standard deviation | 12 | 18 | 18 | 19 | 22 | 22 |
| | of thickness (%) | | | | | | |
| Polystyrene | Refractive index | 1.59 | 1.59 | 1.59 | 1.59 | 1.59 | 1.59 |
| layer | Mean thickness (μm) | 0.049 | 0.049 | 0.057 | 0.057 | 0.068 | 0.067 |
| | Standard deviation | 10 | 7 | 10 | 11 | 28 | 27 |
| | of thickness (%) | | | | | | |

Notes:
1. The mean thickness and the standard deviation were the same for all polymethyl methacrylate layers.
2. The mean thickness and the standard deviation were the same for all polystyrene layers.
3. The mean layer thickness is the average of all layers.

The volume mean particle diameter, the mean circularity, the mean layer thickness, the number (n) of layers and the refractive index were measured by the following methods.

### (1) Evaluation of Volume Mean Particle Diameter and Mean Circularity

A dispersion liquid was prepared by mixing 1 part of a multilayer structured spherical particle, 1 part of sodium dodecylbenzenesulfonate, and 98 parts of ion exchange water and applying an ultrasonic wave for 30 minutes. The volume mean particle diameter and the mean circularity of this dispersion liquid were measured using a flow type particle image analyser [produced by Sysmex Corp.; FPIA-3000].

### (2) Measurement of Mean Layer Thickness and Number (n) of Layers

A multilayer structured spherical particle was uniformly dispersed in an epoxy resin {EPIKOTE 828, produced by Japan Epoxy Resins Co., Ltd.; “EPIKOTE” is a registered trademark of Resolution Research Netherland Besloten Vennootschap} and hardened on heating. The hardened product was cut with a microcutter and the section was observed by a transmission electron microscope (TEM). The thickness was measured at ten points for one layer and the average value of the measurements was calculated.

The number (n) of layers was checked by observing the section.

### (3) Measurement of Refractive Index of Individual Layers

In the case of a resin layer, a sample for measurement was prepared by applying a resin solution with an applicator. On the other hand, in the case of a metal oxide layer, a sample for measurement was prepared by a sol-gel method.

The sample, which was a thin film, was measured for its refractive index at 25° C. using an Abbe refractometer [produced by Atago Co., Ltd.: NAR-4T].

### Comparative Examples 1 to 6

The following pigments <1 to 3> or dyes <4 to 6> were used as comparative particles 1 to 6.

### <1> C.I. Pigment Blue 15

<2> Mixed pigment prepared by uniformly mixing 12 parts of C. I. Pigment Green 36 and 3 parts of C.I. Pigment Yellow 150
<3> Mixed pigment prepared by uniformly mixing 10 parts of C.I. Pigment Red 254 and 5 parts of C.I. Pigment Red 177

### <4> Dye {Acid Blue}

### <5> Dye {Mordant Green}

### <6> Dye {Acid Red}

For the multilayer structured spherical particles obtained in Examples 1 to 24, the color emission property and the wavelength of transmitted light were evaluated by the following methods and the results are shown in Table 5. Evaluations were made for the spherical particles obtained in Production Examples 2 to 16 in the same manner. All the samples showed neither color emission nor a peak top.

### <Color Emission Property>

A dispersion liquid was prepared by mixing 13 parts of polyvinyl alcohol [PVA205: produced by Kuraray Co., Ltd.], 6 parts of polyvinyl pyrrolidone [PVP-K30: produced by Gokyo Trading Co., Ltd.], 173 parts of methanol, 211.4 parts of water, and 15 parts of a sample for evaluation {a multilayer structured spherical resin particle or a comparative particle} {the amount of the dye was adjusted to 5 parts} and applying an ultrasonic wave for 1 hour. This dispersion liquid was applied to a glass substrate (50 mm×50 mm) so that the thickness of the liquid film became 20 μm with an applicator and then dried at 80° C. for 4 hours. Thus, a treated substrate was obtained.

Light emitted from a white color LED was applied to the treated substrate on its rear side and the light transmitted through the treated substrate was visually observed.

### <Wavelength of Transmitted Light>

The wavelength of the light transmitted through a treated substrate was measured using a UV-Visible spectrometer [produced by Shimadzu Corp.: UV-2400PC] and the wavelength of the light having a peak top was used as the wavelength of the transmitted light.

In FIGS. 1 to 4, provided are graphs showing the wavelength and transmittance of the light transmitted through the treated substrates prepared using multilayer spherical particles obtained in Examples 2 (CF-2), 4 (CF-4), 6 (CF-6), 8 (CF-8), 10 (CF-10) and 12 (CF-12) and comparative particles.

TABLE 5

| | Example | | | | | | | |
|---|---|---|---|---|---|---|---|---|
| | 1 | 2 | 3 | 4 | 5 | 6 | 7 | 8 |
| Multilayer structured | LB-4 | LB-5 | LB-7 | LB-8 | LB-10 | LB-11 | LB-13 | LB-14 |
| particle | | | | | | | | |
| Color emission | Blue | Blue | Green | Green | Red | Red | Blue | Blue |
| property | | | | | | | | |
| Wavelength (nm) of | 485 | 482 | 530 | 525 | 633 | 657 | 479 | 476 |
| transmitted light | | | | | | | | |
| | Example | | | | | | | |
| | 9 | 10 | 11 | 12 | 13 | 14 | 15 | 16 |
| Multilayer structured | LB-16 | LB-17 | LB-19 | LB-20 | LB-22 | LB-23 | LB-25 | LB-26 |
| particle | | | | | | | | |
| Color emission | Green | Green | Red | Red | Blue | Blue | Green | Green |
| property | | | | | | | | |
| Wavelength (nm) of | 522 | 515 | 647 | 640 | 480 | 483 | 532 | 529 |
| transmitted light | | | | | | | | |
| | Example | | | | | | | |
| | 17 | 18 | 19 | 20 | 21 | 22 | 23 | 24 |
| Multilayer structured | LB-28 | LB-29 | LB-32 | LB-33 | LB-35 | LB-36 | LB-38 | LB-39 |
| particle | | | | | | | | |
| Color emission | Red | Red | Blue | Blue | Green | Green | Red | Red |
| property | | | | | | | | |
| Wavelength (nm) of | 630 | 638 | 477 | 477 | 521 | 520 | 648 | 643 |
| transmitted light | | | | | | | | |

### <Light Resistance>

After applying UV light from a UV lamp to the treated substrates prepared using multilayer spherical particles obtained in Examples 2 (CF-2), 4 (CF-4), 6 (CF-6), 8 (CF-8), (CF-10) and 12 (CF-12) and comparative particles for 1000 hours, the transmitted light was measured in the same manner as described above. In FIGS. 5 to 8, provided are graphs showing the wavelength and transmittance of the light transmitted through the treated substrates.

Comparison of FIGS. 1, 2 and FIG. 3 shows that when a multilayer structured particle of the present invention was used (FIGS. 1 and 2), the range of the wavelength of the light transmitted is narrow and the color purity is high.

Comparison of FIGS. 1, 2 and FIG. 4 shows that when a multilayer structured particle of the present invention was used (FIGS. 1 and 2), the range of the wavelength of the light transmitted is a little narrow and the color purity is high.

In comparison of FIGS. 5, 6 and FIG. 7, no difference in light resistance was found.

Comparison of FIGS. 5, 6 and FIG. 8 shows that use of multilayer structured particles of the present invention (FIGS. 5 and 6) resulted in better light resistance.

As shown above, multilayer structured spherical particles of the present invention are remarkably better in color purity and light resistance in comparison with conventional colorants (pigments and dyes).

### Production Example 17

### Production of a Titania Non-Spherical Particle (Central Layer)

200 parts of titanium tetraisopropoxide, 750 parts of methyl ethyl ketone, and 20 parts of polyvinyl pyrrolidone (number-average molecular weight: 40000) were mixed uniformly and then heated to 50° C., followed by dropping of 2 parts of 1% aqueous ammonia solution over 30 minutes. After the dropping, the mixture was heated to 80° C. and subjected to a reaction for 8 hours. Thus, a dispersion liquid containing a non-spherical titania particle (LB-40) was obtained. The non-spherical titania particle (LB-40) {volume mean particle diameter: 2.7 μm; mean circularity: 0.91} was obtained by subjecting the dispersion liquid to centrifugal separation, washing with water, and drying.

### Production Example 18

A water phase was obtained by uniformly mixing 800 parts of ion exchange water and 5 parts of sodium dodecylbenzenesulfonate. On the other hand, an oil layer was obtained by uniformly mixing 100 parts of styrene, 80 parts of divinylbenzene, 5 parts of azobisbutyronitrile, and 15 parts of an anionic reactive surfactant {ELEMINOL JS-2: produced by Sanyo Chemical Industries, Ltd.}. Then, the entire portion of the oil layer was added to the water phase, followed by stirring at 4000 rpm for 1 minute with a rotor-stator disperser [TK homomixer: produced by Tokushu Kika Kogyo Co., Ltd.]. The mixture was transferred to a pressure-resistant vessel equipped with a stirrer and then subjected to a reaction at 85° C. for 12 hours. Thus, a dispersion liquid containing a non-spherical resin particle (LB-41) was obtained. The non-spherical resin particle (LB-41) {volume mean particle diameter: 5.3 μm; mean circularity: 0.92} was obtained by subjecting the dispersion liquid to centrifugal separation, washing with water, and drying.

### Production Example 19

After mixing 900 parts of ion exchange water and 50 parts of the non-spherical resin particle (LB-41) and irradiating the mixture with an ultrasonic wave for 30 minutes, 3 parts of a cationic reactive surfactant (S-1) was added and the mixture was stirred for 4 hours. Thus, a dispersion liquid was obtained. On the other hand, after uniformly mixing 3 parts of methyl methacrylate, 1.7 parts of divinylbenzene, 0.03 parts of an anionic reactive surfactant [ELEMINOL JS-2: produced by Sanyo Chemical Industries, Ltd.], and 0.2 parts of azobisbutyronitrile, the mixed liquid was added to the dispersion liquid, followed by stirring for 30 minutes. Thus, a mixed dispersion liquid was obtained. The mixed dispersion liquid was transferred to a pressure-resistant vessel equipped with a stirrer and subjected to a reaction at 85° C. for 12 hours. Thus, a dispersion liquid containing a two-layer structured non-spherical particle (LB-42) was obtained. The two-layer structured non-spherical particle (LB-42) {volume mean particle diameter: 6.3 μm; mean circularity: 0.92} was obtained by subjecting the dispersion liquid to centrifugal separation, washing with water, and drying.

### Production Example 20

950 parts of ion exchange water, 45 parts of the non-spherical titania particle (LB-40), and sodium dodecylbenzenesulfonate were mixed and an ultrasonic wave was applied for 30 minutes to yield a dispersion liquid. This dispersion liquid was charged into a chamber of a submerged-type laser ablation system [produced by Nara Machinery Co., Ltd.]. A lump of polytetrafluoroethylene was set in the dispersion liquid and this lump was irradiated with laser for 3 hours. Thus, polytetrafluoroethylene was vapor-deposited on the surface of the non-spherical titania particle (LB-40). Thus, a dispersion liquid containing a two-layer structured non-spherical particle (LB-45) was obtained. The two-layer structured non-spherical particle (LB-45) {volume mean particle diameter: 3.2 μm; mean circularity: 0.91} was obtained by subjecting the dispersion liquid to centrifugal separation, washing with water, and drying.

### Production Example 21

While 550 parts of acetone, 132 parts of diethanolamine, 268 parts of hexamethylene diisocyanate, and 10 parts of dibutyltin dilaurate were mixed uniformly, a reaction was carried out at 80° C. for 12 hours. Then, 40 parts of dimethyl sulfate was added, followed by a reaction at 50° C. for 8 hours. Thus, a cationic resin solution was obtained.

Then, while 500 parts of ion exchange water was stirred at 8000 rpm using a rotor-stator disperser [TK homomixer: produced by Tokushu Kika Kogyo Co., Ltd.], 500 parts of a cationic resin solution was charged thereinto, followed by stirring for 1 minute. Following evaporation of acetone under reduced pressure (35° C., 12 hours}, a dispersion liquid {volume mean particle diameter: 0.03 μm} containing a cationic resin particle (EB-1) was obtained.

### Production Example 22

A water phase was obtained by uniformly mixing 700 parts of ion exchange water, 20 parts of sodium dodecylbenzenesulfonate and 5 parts of ammonium persulfate. On the other hand, an oil phase was obtained by uniformly mixing 80 parts of styrene, 60 parts of methacrylic acid, and 60 parts of methyl methacrylate. Subsequently, the water phase was heated to 80° C. and then the oil phase was dropped thereto over 2 hours, followed by a reaction for 4 hours. Then, 2 parts of ammonium persulfate was added, followed by a reaction for 4 hours. Thus, a dispersion liquid {volume mean particle diameter: 0.04 μm} containing an anionic resin particle (EB-2) was obtained.

### Production Example 23

A water phase was obtained by uniformly mixing 800 parts of ion exchange water and 5 parts of sodium dodecylbenzenesulfonate. On the other hand, an oil layer was obtained by uniformly mixing 80 parts of styrene, 60 parts of methacrylic acid, 60 parts of methyl methacrylate, 20 parts of divinylbenzene, 5 parts of azobisbutyronitrile, and 15 parts of an anionic reactive surfactant {ELEMINOL JS-2: produced by Sanyo Chemical Industries, Ltd.}. Then, the entire portion of the oil layer was added to the water phase, followed by stirring at 4000 rpm for 1 minute with a rotor-stator disperser [TK homomixer: produced by Tokushu Kika Kogyo Co., Ltd.]. The mixture was transferred to a pressure-resistant vessel equipped with a stirrer and then subjected to a reaction at 85° C. for 12 hours. Thus, a dispersion liquid containing a non-spherical resin particle (LB-48) was obtained. The non-spherical resin particle (LB-48) {volume mean particle diameter: 4.1 μm; mean circularity: 0.91} was obtained by subjecting the dispersion liquid to centrifugal separation, washing with water, and drying.

### Production Example 24

A dispersion liquid containing a two-layer structured non-spherical resin particle (LB-49) was obtained by uniformly mixing 700 parts of ion exchange water, 50 parts of the non-spherical resin particle (LB-48), 5 parts of NAROACTY N40 (an alkylalcohol-ethylene oxide adduct: produced by Sanyo Chemical Industries, Ltd.) and 1 part of hydrochloric acid, adding 50 parts of a dispersion liquid containing a cationic resin particle (EB-1) thereto, and stirring for 1 hour. The two-layer structured non-spherical resin particle (LB-49) {volume mean particle diameter: 4.2 μm; mean circularity: 0.91} was obtained by subjecting the dispersion liquid to centrifugal separation, washing with water, and drying.

### Example 25

A three-layer structured non-spherical particle (LB-43) having a crosslinked polystyrene layer-crosslinked polymethyl methacrylate layer-crosslinked polystyrene layer structure {volume mean particle diameter: 7.4 μm, mean circularity: 0.92} was obtained in the same manner as in Production Example 19 except changing “non-spherical resin particle (LB-41)” to “two-layer structured non-spherical particle (LB-42)” and changing “methyl methacrylate” to “styrene.

### Example 26

A four-layer structured non-spherical particle (LB-44) having a polystyrene layer-polymethyl methacrylate layer-polystyrene layer-methyl methacrylate layer structure {volume mean particle diameter: 8.4 μm, mean circularity: 0.93} was obtained in the same manner as in Production Example 19 except changing “non-spherical resin particle (LB-41)” to “three-layer structured non-spherical particle (LB-43).”

### Example 27

A three-layer structured non-spherical particle (LB-46) having a titania layer-polytetrafluoroethylene layer-titania layer structure {volume mean particle diameter: 4.0 μm, mean circularity: 0.92} was obtained in the same manner as in Production Example 20 except changing “non-spherical titania particle (LB-40)” to “two-layer structured non-spherical particle (LB-45)” and changing “polytetrafluoroethylene” to “titania.”

### Example 28

A four-layer structured non-spherical particle (LB-47) having a titania layer-polytetrafluoroethylene layer-titania layer-polytetrafluoroethylene layer structure {volume mean particle diameter: 4.7 μm, mean circularity: 0.93} was obtained in the same manner as in Production Example 20 except changing “non-spherical titania particle (LB-40)” to “three-layer structured non-spherical particle (LB-46).”

### Example 29

A dispersion liquid containing a three-layer structured non-spherical resin particle (LB-50) was obtained by uniformly mixing 700 parts of ion exchange water, 50 parts of two-layer structured non-spherical particle (LB-49) and 5 parts of NAROACTY N40 (an alkylalcohol-ethylene oxide adduct: produced by Sanyo Chemical Industries, Ltd.), adding 50 parts of a dispersion liquid containing an anionic resin particle (EB-2) thereto, and stirring for 1 hour. The three-layer structured non-spherical resin particle (LB-50) {volume mean particle diameter: 4.3 μm; mean circularity: 0.92} was obtained by subjecting the dispersion liquid to centrifugal separation, washing with water, and drying.

### Example 30

A four-layer structured non-spherical resin particle was obtained in the same manner as in Production Example 24 except changing “non-spherical resin particle (LB-48)” to “three-layer structured non-spherical resin particle (LB-50).” Then, a five-layer structured non-spherical resin particle was obtained in the same manner as in Production Example 24 except changing “non-spherical resin particle (LB-48)” to “four-layer structured non-spherical resin particle” and changing “a dispersion liquid containing a cationic resin particle (EB-1)” to “a dispersion liquid containing an anionic resin particle (EB-2).” Then, a ten-layer structured non-spherical particle (LB-51) {volume mean particle diameter: 4.1 μm, mean circularity: 0.93} was obtained by repeating the same operations as those in Production Example 24 except changing “multilayer structured spherical particle” and changing “a dispersion liquid containing a cationic resin particle (EB-1)” and “a dispersion liquid containing an anionic resin particle (EB-2)” to one after another.

For the multilayer structured particles obtained in Examples 25 to 30, the number (n) of layers, the volume mean particle diameter, the mean circularity, the refractive index of individual layers, and the volume of the central layer (L0) are shown in Table 6. The number (n) of layers, the volume mean particle diameter, the mean circularity and the refractive index of individual layers were obtained in the same manner as described above.

TABLE 6

| | | Example | | | | | |
|---|---|---|---|---|---|---|---|
| | | 25 | 26 | 27 | 28 | 29 | 30 |
| Multilayer structured particle | | LB-43 | LB-44 | LB-46 | LB-47 | LB-50 | LB-51 |
| Number of layers | | 3 | 4 | 3 | 4 | 3 | 10 |
| Volume mean particle diameter (μm) | | 7.4 | 8.4 | 4 | 4.7 | 4.3 | 5.1 |
| Mean circularity | | 0.92 | 0.93 | 0.92 | 0.93 | 0.92 | 0.93 |
| Mean layer thickness (μm) | | 0.6 | 0.5 | 0.4 | 0.4 | 0.5 | 0.5 |
| Polymethyl | Refractive index | 1.49 | 1.49 | — | — | — | — |
| methacrylate | Mean thickness (μm) | 0.6 | 0.5 | — | — | — | — |
| layer | Standard deviation | 25 | 24 | — | — | — | — |
| | of thickness (%) | | | | | | |
| Polystyrene | Refractive index | 1.59 | 1.59 | — | — | — | — |
| layer | Mean thickness (μm) | 0.6 | 0.5 | — | — | — | — |
| | Standard deviation | 27 | 22 | — | — | — | — |
| | of thickness (%) | | | | | | |
| Polyfluoroethylene | Refractive index | — | — | 1.42 | 1.42 | — | — |
| layer | Mean thickness (μm) | — | — | 0.4 | 0.4 | — | — |
| | Standard deviation | — | — | 8 | 9 | — | — |
| | of thickness (%) | | | | | | |
| Titania | Refractive index | — | — | 2.76 | 2.76 | — | — |
| layer | Mean thickness (μm) | — | — | 0.4 | 0.4 | — | — |
| | Standard deviation | — | — | 7 | 7 | — | — |
| | of thickness (%) | | | | | | |
| Cationic | Refractive index | — | — | — | — | 1.55 | 1.55 |
| resin layer | Mean thickness (μm) | — | — | — | — | 0.4 | 0.5 |
| | Standard deviation | — | — | — | — | 27 | 28 |
| | of thickness (%) | | | | | | |
| Anionic | Refractive index | — | — | — | — | 1.5 | 1.5 |
| resin layer | Mean thickness (μm) | — | — | — | — | 0.6 | 0.5 |
| | Standard deviation | — | — | — | — | 28 | 29 |
| | of thickness (%) | | | | | | |

Notes:
1. The mean thickness and the standard deviation were the same for all polymethyl methacrylate layers.
2. The mean thickness and the standard deviation were the same for all polystyrene layers.
3. The mean thickness and the standard deviation were the same for all polyfluoroethylene layers.
4. The mean thickness and the standard deviation were the same for all titania layers.
5. The mean thickness and the standard deviation were the same for all cationic resin layers.
6. The mean thickness and the standard deviation were the same for all anionic layers.
7. The mean layer thickness is the average of all layers.

For the multilayer structured non-spherical particles obtained in Examples 25 to 30, the total light transmittance and the haze were evaluated by the following methods and the results are shown in Table 7. The same evaluations were made for the non-spherical particles obtained in Production Examples 17, 18, and 23.

### <Total Light Transmittance and Haze>

A dispersion liquid was obtained by mixing 189 parts of methyl methacrylate, 1 part of a photopolymerization initiator [IRGNOX 1010: produced by Ciba Specialty Chemicals] and 10 parts of a sample for evaluation {a multilayer structured non-spherical particle or a non-spherical particle} and applying an ultrasonic wave for 5 minutes. This dispersion liquid was applied to a glass substrate (50 mm×50 mm) so that the thickness of the liquid film became 200 μm with an applicator and then irradiated for 10 seconds with UV light emitted from a UV lamp. Thus, a resin film (A) was obtained.

A resin film (B) was formed in the same manner as described above except changing the amount of methyl methacrylate from “189 parts” to “169 parts” and the amount of a sample for evaluation from “10 parts” to “30 parts.

Using a haze meter NDH2000 (produced by Nippon Denshoku Industries Co., Ltd.), the total light transmittance and haze of the resin film (A) or (B) {including the glass substrate} were measured. The evaluation results of the resin film (A) and those of the resin film (B) are shown in Table 7 and Table 8, respectively.

The higher the haze is, the higher the light scattering property; the higher the total light transmittance is, the smaller the loss of light.

TABLE 7

| | Example | | | | | |
|---|---|---|---|---|---|---|
| | 25 | 26 | 27 | 28 | 29 | 30 |
| Multilayer structured particle | LB-43 | LB-44 | LB-46 | LB-47 | LB-50 | LB-51 |
| Addition amount (% by | 5 | 5 | 5 | 5 | 5 | 5 |
| weight) | | | | | | |
| Total light | 99 | 98 | 99 | 98 | 98 | 99 |
| transmittance (%) | | | | | | |
| Haze (%) | 95 | 96 | 97 | 97 | 97 | 99 |

| | Production Example | | |
|---|---|---|---|
| | 17 | 18 | 23 |
| Multilayer structured particle | LB-40 | LB-41 | LB-48 |
| Addition amount (% by | 5 | 5 | 5 |
| weight) | | | |
| Total light | 90 | 88 | 87 |
| transmittance (%) | | | |
| Haze (%) | 88 | 79 | 87 |

TABLE 8

| | Example | | | | | |
|---|---|---|---|---|---|---|
| | 25 | 26 | 27 | 28 | 29 | 30 |
| Multilayer structured particle | LB-43 | LB-44 | LB-46 | LB-47 | LB-50 | LB-51 |
| Addition amount (% by | 15 | 15 | 15 | 15 | 15 | 15 |
| weight) | | | | | | |
| Total light | 98 | 98 | 98 | 97 | 97 | 99 |
| transmittance (%) | | | | | | |
| Haze (%) | 97 | 98 | 98 | 98 | 96 | 98 |

| | Production Example | | |
|---|---|---|---|
| | 17 | 18 | 23 |
| Multilayer structured particle | LB-40 | LB-41 | LB-48 |
| Addition amount (% by | 15 | 15 | 15 |
| weight) | | | |
| Total light | 83 | 76 | 85 |
| transmittance (%) | | | |
| Haze (%) | 90 | 92 | 75 |

The resin films prepared by use of the multilayer structured non-spherical particles obtained in Examples 25 to were excellent in both haze and total light transmittance, which are essentially in trade-off relation. On the other hand, the non-spherical particles obtained in Production Examples 17, 18, and 23 were poor in both haze and total light transmittance.

### INDUSTRIAL APPLICABILITY

The multilayer structured particle of the present invention is extremely useful as a colorant for use in a color filter for displays or as a light diffusion film, a light diffusion plate, a light guide plate or an anti-glare film for displays.

1. A multilayer structured particle having a structure in which a central layer (L0) is provided as a core and two or more layers (Ln) are disposed concentrically with respect to the center of the core, wherein every pair of adjacent layers has a refractive index difference (at 25° C.) of from 0.01 to 1.5 and at least one layer of the central layer (L0) and the layers (Ln) is a metal oxide layer (M).

2. The multilayer structured particle according to claim 1, wherein at least one layer of the layers (Ln) has an average thickness of from 0.01 to 3 μm.

3. The multilayer structured particle according to claim 1, wherein a standard deviation of the thickness of at least one layer of the layers (Ln) is not more than 30%.

4. The multilayer structured particle according to claim 1, wherein a volume mean particle diameter is from 0.1 to 20 μm.

5. The multilayer structured particle according to claim 1, wherein a volume of the central layer (L0) based on the volume of the multilayer structured particle is from 5 to 98% by volume.

6. The multilayer structured particle according to claim 1, wherein at least one layer and at least another one layer of the central layer (L0) and the layers (Ln) are a resin layer (R) and a metal oxide layer (M), respectively.

7. The multilayer structured particle according to claim 6, wherein the resin layer (R) comprises a crosslinked resin.

8. The multilayer structured particle according to claim 6, wherein the particle has a structure in which the resin layer (R) and the metal oxide layer (M) are disposed alternately one on another.

9. The multilayer structured particle according to claim 6, wherein the resin layer (R) is at least one substance selected from the group consisting of polyurethane, polyester, vinyl resin, fluororesin, and polyamide.

10. The multilayer structured particle according to claim 1, wherein the metal oxide layer (M) is at least one substance selected from the group consisting of silica, alumina, magnesium oxide, zinc oxide, and titanium oxide.

11. The multilayer structured particle according to claim 1, wherein the central layer (L0) is a metal oxide layer (M).

12. The multilayer structured particle according to claim 1, wherein at least one layer of the central layer (L0) and the layers (Ln) contains at least one substance selected from the group consisting of dyes, pigments, and fluorescent materials.

13. The multilayer structured particle according to claim 1, wherein the particle is a spherical particle with a mean circularity of from 0.96 to 1.

14. The multilayer structured particle according to claim 1, wherein the particle is a non-spherical particle with a mean circularity of not less than 0.7 but less than 0.96.

15. A color filter for displays comprising the multilayer structured particle according to claim 13.

16. A resin film comprising the multilayer structured particle according to claim 13.

17. A coating material comprising the multilayer structured particle according to claim 13.

18. A light diffusion film comprising the multilayer structured particle according to claim 14.

19. A method for producing a multilayer structured particle comprising: at least two steps, a repetition of at least two steps, or a repetition of at least one step selected from the group consisting of production steps (10), (20), (30), and (40):
production step (10) of obtaining a multilayer structured particle by obtaining a multilayer particle dispersion liquid by placing a lump of a resin or a metal oxide in a dispersion liquid (D0) containing a central layer (L0) dispersed therein or a dispersion liquid (Dn) containing a multilayer particle dispersed therein and applying a pulse laser to the lump to generate fine particles and thereby form a resin layer (R) or a metal oxide layer (M) on the surface of the central layer (L0) or the multilayer particle;
production step (20) of obtaining a multilayer structured particle by reacting either a central layer (L0) having a reactive group (a) or a multilayer particle having a reactive group (a) in its surface and a gaseous metal compound together by heating to form a metal compound layer on the surface of the central layer (L0) or the multilayer particle and thereby obtain a metal compound layer particle, then removing the unreacted gaseous metal compound, and reacting the metal compound layer particle and water vapor together to change the metal compound layer into a metal oxide layer (M) to obtain a multilayer particle;
production step (30) of obtaining a multilayer structured particle by including at least one step selected from
step (31) of obtaining a multilayer particle dispersion liquid by adding a metal alkoxide to a dispersion liquid (D0) containing a central layer (L0) of a resin having active hydrogen dispersed in an alcohol having 1 to 4 carbon atom(s) or an aprotic solvent (E31) or a dispersion liquid (Dn) containing a multilayer particle having a surface composed of a resin layer having active hydrogen dispersed in an alcohol having 1 to 4 carbon atom(s) or an aprotic solvent (E31) to thereby form a metal oxide layer on the surface of the central layer (L0) or the multilayer particle by a sol-gel method;
step (32) comprising adding, to a dispersion liquid containing a cationic or anionic reactive surfactant (S1) which is copolymerizable with a resin precursor (m) and a multilayer particle having a metal oxide layer on its surface or a central layer (L0) composed of a metal oxide, a reactive surfactant (S2) which is copolymerizable with the resin precursor (m) and has the opposite ionicity to that of the reactive surfactant (S1), and the resin precursor (m), then copolymerizing the reactive surfactant (S1), the reactive surfactant (S2), and the resin precursor (m) to form a resin layer on the surface of the multilayer particle or the central layer (L0) to thereby obtain a multilayer particle dispersion liquid, and then isolating a multilayer particle;
step (33) comprising adding, to a dispersion liquid containing a cationic or anionic reactive surfactant (S1) which is copolymerizable with a resin precursor (m) and a multilayer particle having a resin layer on its surface or a central layer (L0) composed of a resin, a reactive surfactant (S2) which is copolymerizable with the resin precursor (m) and has the opposite ionicity to that of the reactive surfactant (S1), and the resin precursor (m), then copolymerizing the reactive surfactant (S1), the reactive surfactant (S2), and the resin precursor (m) to form a resin layer on the surface of the multilayer particle or the central layer (L0) to thereby obtain a multilayer particle dispersion liquid, and then isolating a multilayer particle; and
step (34) of obtaining a multilayer particle dispersion liquid by adding a metal alkoxide to a dispersion liquid (D0) containing a central layer (L0) of a metal oxide having active hydrogen dispersed in an alcohol having 1 to 4 carbon atom(s) or an aprotic solvent (E31) or a dispersion liquid (Dn) containing a multilayer particle having a surface composed of a metal oxide layer having active hydrogen dispersed in an alcohol having 1 to 4 carbon atom(s) or an aprotic solvent (E31) to thereby form a metal oxide layer on the surface of the central layer (L0) or the multilayer particle by a sol-gel method; and
production step (40) of obtaining a multilayer structured particle by obtaining a multilayer particle dispersion liquid by adding a metal alkoxide to a dispersion liquid (D0) containing a central layer (L0) of a resin or a metal oxide having active hydrogen dispersed in an alcohol having 1 to 4 carbon atom(s) or an aprotic solvent (E31) or a dispersion liquid (Dn) containing a multilayer particle having a surface composed of a resin layer or a metal oxide layer having active hydrogen dispersed in an alcohol having 1 to 4 carbon atom(s) or an aprotic solvent (E31) to thereby form a metal oxide layer on the surface of the central layer (L0) or the multilayer particle by a sol-gel method.

20. A method for producing a multilayer structured particle comprising:
production step (50) comprising adding, to a dispersion liquid containing a cationic or anionic reactive surfactant (S1) which is copolymerizable with a resin precursor (m) and a central layer (L0) composed of a resin or a multilayer particle having a surface composed of a resin layer, a reactive surfactant (S2) which is copolymerizable with the resin precursor (m) and has the opposite ionicity to that of the reactive surfactant (S1), and the resin precursor (m), then copolymerizing the reactive surfactant (S1), the reactive surfactant (S2), and the resin precursor (m) to form a resin layer on the surface of the central layer (L0) or the multilayer particle to thereby obtain a multilayer particle dispersion liquid, subsequently isolating a multilayer particle, and repeating the foregoing operations to obtain a multilayer structured particle; or
production step (60) of obtaining a multilayer structured particle by adding, to a dispersion liquid (D0) containing a central layer (L0) dispersed therein which is composed of a resin and whose surface has a charge (q) or a dispersion liquid (Dn) containing a multilayer particle dispersed therein whose surface is composed of a resin layer and has a charge (q), a resin particle (P0) having a particle diameter as small as 1/10 or less of the particle diameter of the central layer (L0) or the multilayer particle and having a charge (r) with a sign opposite to that of the charge (q) to form a resin layer composed of the resin particle (P0) on the surface of the central layer (L0) or the multilayer particle to thereby obtain a multilayer particle dispersion liquid, and repeating the foregoing operation.

21. The production method according to claim 20, wherein in production step (50) the central layer (L0) has a charge (q) in its surface and the charge (q) is a charge with a sign opposite to that of the ionicity of the reactive surfactant (S1).

22. The production method according to claim 20, wherein every pair of adjacent layers of the central layer (L0) and the resin layers formed has a refractive index difference (at 25° C.) of from 0.01 to 0.5.
